(19) United States
(12) Patent Application Publication
(10) Pub. No.: US 2025/0204260 A1
(43) Pub. Date: Jun. 19, 2025

(54) Healable Piezoelectric Composites

(71) Applicant: San Diego State University (SDSU) Foundation, DBA San Diego State University Research Foundation, San Diego, CA (US)

(72) Inventors: Yang Yang, San Diego, CA (US); Qingqing He, San Diego, CA (US)

(73) Assignee: San Diego State University (SDSU) Foundation, DBA San Diego State University Research Foundation, San Diego, CA (US)

(21) Appl. No.: 18/978,635

(22) Filed: Dec. 12, 2024

Related U.S. Application Data
(60) Provisional application No. 63/611,067, filed on Dec. 15, 2023.

(51) Int. Cl. H10N 30/092; B33Y 80/00; C07F 1/04; C07F 1/06; F41H 5/007; H10N 30/85

(52) U.S. Cl. CPC H10N 30/092; H10N 30/85; B33Y 80/00; C07F 1/04; C07F 1/06; F41H 5/007

(57) ABSTRACT

Systems for piezoelectric composite materials are described. Various piezoelectric composite material structures and configurations can be incorporated into piezoelectric panels. Various methods are described to recycle and heal various piezoelectric composite materials.

### CROSS-REFERENCES TO RELATED APPLICATIONS

The current application claims the benefit of Provisional Application No. 63/711,067, filed Dec. 15, 2023, the disclosure of which is incorporated herein by reference.

### STATEMENT REGARDING FEDERALLY SPONSORED RESEARCH

This invention was made with Government support under Grant No. CMMI-2113727 awarded by the National Science Foundation. The Government has certain rights in this invention.

### FIELD OF THE INVENTION

This disclosure generally refers to systems and methods for a bioinspired piezoelectric composite material.

### BACKGROUND

Bionic multifunctional structural materials for bio-monitoring are based on soft piezoelectric materials or flexible printed circuit boards lack protective capability. Advanced armors are conventionally assembled from strong organic fibers, metals, or inorganic ceramics—i.e., the materials that do not work as sensors. As such, devices aimed at bio-monitoring do not provide any structural protection.

### SUMMARY OF THE INVENTION

Systems and methods in accordance with some embodiments of the invention are directed to a piezoelectric composite material

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

In some embodiments, the techniques described herein relate to a piezoelectric composite material including: a scaffold including an irregular internal structure further including a plurality of voids, channels, and wall-septa; a sensing material including piezoelectric properties disposed within the irregular internal structure of the scaffold, and wherein the sensing material crystallizes within the irregular internal structure.

In some embodiments, the techniques described herein relate to a piezoelectric composite material, wherein the irregular internal structure further includes interconnected channels.

In some embodiments, the techniques described herein relate to a piezoelectric composite material, wherein the irregular internal structure includes a bio-inspired structure.

In some embodiments, the techniques described herein relate to a piezoelectric composite material, wherein the bio-inspired structure resembles a cuttlefish bone microstructure.

In some embodiments, the techniques described herein relate to a piezoelectric composite material, wherein the scaffold is 3D-printed.

In some embodiments, the techniques described herein relate to a piezoelectric composite material, wherein the scaffold accounts for 20% of a piezoelectric composite material total volume.

In some embodiments, the techniques described herein relate to a piezoelectric composite material, wherein the sensing material accounts for 80% of the piezoelectric composite material total volume.

In some embodiments, the techniques described herein relate to a piezoelectric composite material, wherein the sensing material includes a Rochelle salt.

In some embodiments, the techniques described herein relate to a piezoelectric composite material, wherein the sensing material is allowed to crystallize for 24 hours.

In some embodiments, the techniques described herein relate to a piezoelectric composite material, wherein the sensing material crystallizes within the scaffold such that the sensing material substantially fills the entirety of the plurality of voids and channels of the irregular internal structure of the scaffold.

In some embodiments, the techniques described herein relate to a piezoelectric panel including a plurality of piezoelectric composite materials further including: a scaffold including an irregular internal structure further including a plurality of voids, channels, and wall-septa; a sensing material including piezoelectric properties disposed within the irregular internal structure of the scaffold, and wherein the sensing material crystallizes within the irregular internal structure.

In some embodiments, the techniques described herein relate to a piezoelectric panel, wherein the irregular internal structure further includes interconnected channels.

In some embodiments, the techniques described herein relate to a piezoelectric panel, wherein the irregular internal structure includes a bio-inspired structure.

In some embodiments, the techniques described herein relate to a piezoelectric panel, wherein the bio-inspired structure resembles a cuttlefish bone microstructure.

In some embodiments, the techniques described herein relate to a piezoelectric panel, wherein the scaffold is 3D-printed.

In some embodiments, the techniques described herein relate to a piezoelectric panel, wherein the scaffold accounts for 20% of a piezoelectric composite material total volume.

In some embodiments, the techniques described herein relate to a piezoelectric panel, wherein the sensing material accounts for 80% of the piezoelectric composite material total volume.

In some embodiments, the techniques described herein relate to a piezoelectric panel, wherein the sensing material includes a Rochelle salt.

In some embodiments, the techniques described herein relate to a piezoelectric panel, wherein the sensing material is allowed to crystallize for 24 hours.

In some embodiments, the techniques described herein relate to a piezoelectric panel, wherein the sensing material crystallizes within the scaffold such that the sensing material substantially fills the entirety of the plurality of voids and channels.

In some embodiments, the techniques described herein relate to a piezoelectric panel, wherein the piezoelectric panel is incorporated into smart armor.

In some embodiments, the techniques described herein relate to a piezoelectric panel, wherein the piezoelectric panel is incorporated into a smart knee pad further including a buzzer and a light.

In some embodiments, the techniques described herein relate to a piezoelectric panel, wherein the buzzer and the light are activated by a piezoelectric output of the piezoelectric composite material.

In some embodiments, the techniques described herein relate to a process for healing a piezoelectric composite material including: identifying a damaged area within the piezoelectric composite material; providing a sensing material solution; injecting the sensing material solution into the identified damaged area of the piezoelectric composite material; allowing the sensing material to crystallize within the piezoelectric composite material.

In some embodiments, the techniques described herein relate to a process, further including heating the sensing material to provide the sensing material solution.

In some embodiments, the techniques described herein relate to a process, further including allowing the sensing material to crystallize for 24 hours.

In some embodiments, the techniques described herein relate to a process, further including allowing the sensing material to crystallize at room temperature.

In some embodiments, the techniques described herein relate to a process, wherein the sensing material includes Rochelle salt.

In some embodiments, the techniques described herein relate to a process for recycling a piezoelectric composite material including: providing heated distilled water; immersing a first piezoelectric composite material including a first scaffold and a first sensing material in the heated distilled water; allowing the first sensing material to dissolve into the heated distilled water; removing the first scaffold from the first sensing material and the heated distilled water solution; immersing a second scaffold in the first sensing material and the heated distilled water solution; allowing the first sensing material to crystallize within the second scaffold.

In some embodiments, the techniques described herein relate to a process, further including immersing the first piezoelectric composite material in the heated distilled water such that the first sensing material completely dissolves.

In some embodiments, the techniques described herein relate to a process, wherein the first scaffold is bare when removed.

In some embodiments, the techniques described herein relate to a process, further including allowing the first sensing material to crystallize within the second scaffold for 24 hours.

In some embodiments, the techniques described herein relate to a process, further including allowing the first sensing material to crystallize within the second scaffold at room temperature.

In some embodiments, the techniques described herein relate to a process, wherein the first sensing material includes a Rochelle salt.

In some embodiments, the techniques described herein relate to a process, wherein at least one of the scaffolds includes an irregular internal structure further including a plurality of voids, channels, and wall-septa.

In some embodiments, the techniques described herein relate to a process to fabricate a piezoelectric composite material including: modelling a scaffold including an irregular internal structure including a plurality of voids, channels, and wall-septa; providing the scaffold modeled; providing a sensing material solution; immersing the scaffold in the sensing material solution; allowing the sensing material to crystallize within the scaffold.

In some embodiments, the techniques described herein relate to a process, wherein the irregular internal structure of the scaffold includes a bio-inspired structure.

In some embodiments, the techniques described herein relate to a process, wherein the bio-inspired structure resembles a cuttlefish bone microstructure.

In some embodiments, the techniques described herein relate to a process, wherein providing the scaffold includes 3D-printing the scaffold.

In some embodiments, the techniques described herein relate to a process, wherein the scaffold accounts for 20% of a piezoelectric composite material total volume

In some embodiments, the techniques described herein relate to a process, wherein the sensing material accounts for 80% of the piezoelectric composite material total volume.

In some embodiments, the techniques described herein relate to a process, wherein the sensing material includes Rochelle salt.

In some embodiments, the techniques described herein relate to a process, wherein the sensing material is allowed to crystallize for 24 hours.

In some embodiments, the techniques described herein relate to a process, further includes allowing the sensing material to grow within the irregular internal structure of the scaffold such that the sensing material substantially fills the plurality of voids and channels of the internal structure of the scaffold.

In some embodiments, the techniques described herein relate to a process, wherein the sensing material is allowed to crystallize at approximately room temperature.

### BRIEF DESCRIPTION OF THE DRAWINGS

The description will be more fully understood with reference to the following figures, which are presented as embodiments of the invention and should not be construed as a complete recitation of the scope of the invention, wherein:

FIG. 1A schematically illustrates an exemplary embodiment of a piezoelectric composite material comprising an irregular scaffold and sensing material.

FIGS. 1B and 1C illustrate an exemplary embodiment of a piezoelectric composite material.

FIGS. 2A to 2D illustrate an exemplary embodiment of a piezoelectric composite material producing an output voltage.

FIGS. 2E to 2H illustrate schematics of an experimental set up of various embodiments and the corresponding electrical output voltage data collected of switched polarity.

FIG. 3 illustrates a process diagram to fabricate various embodiments of piezoelectric composite materials.

FIGS. 4A to 4C schematically illustrate the bio-inspired structure of a cuttlefish bone microstructure.

FIGS. 5A to 5E schematically illustrate exemplary embodiments of a bioinspired scaffold design.

FIG. 6A illustrates a finite element method simulation of the load effect of piezoelectric composite materials in accordance with various embodiments with varying scaffold structures.

FIGS. 6B to 6F illustrate and compare the performance of piezoelectric composite materials in accordance with various embodiments with various scaffold structures.

FIG. 7 schematically illustrates the chemical structure of a sensing material of an exemplary embodiment.

FIG. 8 schematically illustrates the growth of a sensing material within a scaffold in accordance with an exemplary embodiment.

FIGS. 9A to 9E illustrate an exemplary embodiment of sensing material growth within a bioinspired scaffold over a period of time.

FIG. 10 illustrates a computerized tomography scan of an exemplary embodiment

FIGS. 11A to 11E illustrate an energy dispersive X-ray elemental analysis of an exemplary embodiment.

FIGS. 12A to 12F illustrate scanning electron microscopy of sensing material growth within a bioinspired scaffold in accordance with an exemplary embodiment.

FIG. 13 illustrates a computerized tomography scan of an exemplary embodiment after 24 hours of sensing material growth in accordance with an exemplary embodiment.

FIG. 14A illustrates a scanning electron microscopy of sensing material growth within a bioinspired scaffold in accordance with an exemplary embodiment.

FIGS. 14B to 14F illustrate a dispersive X-ray spectroscopy element layered photos sensing material growth within a bioinspired scaffold in accordance with an exemplary embodiment.

FIG. 15 illustrates the voltage output of piezoelectric composite materials when sensing material is grown over different periods of time in accordance with various embodiments.

FIGS. 16A to 16G illustrate the mechanical properties of an exemplary embodiment.

FIG. 17 illustrates differently shaped bioinspired piezoelectric composite materials in accordance with an exemplary embodiment at different feature scales.

FIGS. 18A to 18C illustrate bioinspired scaffolds in accordance with various embodiments with different proportions of scaffold to voids.

FIGS. 18D to 18F illustrate piezoelectric composite materials in accordance with various embodiments with different proportions of scaffold to sensing material after 24 hours of sensing material growth.

FIGS. 19A to 19F illustrate the performance of bioinspired scaffolds in accordance with various embodiments with different proportions of scaffold to sensing material.

FIGS. 20A to 20F illustrate the cyclic impact results of an exemplary embodiment.

FIG. 21 illustrates a scanning electron microscopy of an exemplary embodiment after cyclic impact testing.

FIG. 22 illustrates the piezoelectric properties of various materials.

FIG. 23 illustrates a table of the piezoelectric properties of various materials.

FIG. 24A illustrates the normalized displacement distribution of a piezoelectric composite material in accordance with an exemplary embodiment.

FIG. 24B illustrates the phase of a piezoelectric composite material in accordance with an exemplary embodiment measured using a laser vibrometer.

FIGS. 25A and 25B illustrate the static displacement vs. applied voltage of various embodiments of piezoelectric composite materials.

FIG. 26 illustrates the voltage output of bioinspired scaffolds with various sensing materials in accordance with various embodiments.

FIG. 27 illustrates piezoelectric finite element method simulation of an exemplary embodiment when force is applied in different directions.

FIGS. 28A and 28B illustrate the electrical impedance spectrum used to determine the coupling factor for an exemplary embodiment.

FIGS. 29A to 29E illustrate the properties of a sensing material film and sensing material crystal in accordance with various embodiments.

FIG. 30A shows the process of healing a piezoelectric composite material in accordance with an embodiment.

FIG. 30B schematically illustrates the process of healing a piezoelectric composite material in accordance with an embodiment.

FIG. 30C illustrates the process of healing a piezoelectric composite material in accordance with an exemplary embodiment.

FIGS. 31A and 31B illustrate simulations of stress distribution of a cracked piezoelectric composite material and scanning electron microscopy of a cracked piezoelectric composite material in accordance with an embodiment.

FIG. 32 illustrates R-curves of the bare scaffold and the piezoelectric composite material with different amounts of sensing material in accordance with various embodiments.

FIGS. 33A and 33B illustrate the process for recycling a piezoelectric composite material in accordance with an embodiment.

FIGS. 34A to 34C illustrate the piezoelectric and mechanical performance of a recycled piezoelectric composite material in accordance with various embodiments.

FIG. 35A schematically illustrates an assembly of a piezoelectric panel comprising piezoelectric composite material in accordance with an exemplary embodiment.

FIG. 35B schematically illustrates an exemplary embodiment of a piezoelectric panel in accordance with an embodiment configured as smart armor for a football player.

FIG. 36A illustrates the force magnitude distribution diagram of a piezoelectric panel in accordance with an embodiment.

FIG. 36B illustrates the piezoelectric output of a piezoelectric panel in accordance with an embodiment.

FIG. 37A illustrates data collection experiments using various weights to show the corresponding impact on a piezoelectric panel in accordance with an embodiment.

FIGS. 37B and 37C illustrate the voltage output waveform of a piezoelectric panel in accordance with an embodiment observed upon impact in data collection experiments.

FIGS. 37D and 37E illustrate a MATLAB analysis of the force distribution of an impact data collection experiment of a piezoelectric panel in accordance with an embodiment.

FIG. 37F illustrates the impact force applied to 16 sensing elements of a piezoelectric panel in accordance with an embodiment.

FIG. 38 illustrates a force impact pattern derived from pressure detection distribution on a piezoelectric panel in accordance with an embodiment.

FIGS. 39A to 39G illustrate the performance of a broken and a healed piezoelectric panel in accordance with an embodiment.

FIGS. 40A to 40E illustrate the performance of a recycled piezoelectric panel in accordance with an embodiment.

FIGS. 41A to 41C schematically illustrate a piezoelectric panel incorporated into a smart knee pad.

FIG. 41D illustrates a flow diagram of an experimental set up to test a piezoelectric panel incorporated into a smart knee pad in accordance with an embodiment.

FIGS. 42A to 42F illustrate block distribution diagrams and the voltage output diagrams obtained from the fall tests with a piezoelectric panel incorporated into a smart knee pad in accordance with an embodiment.

FIGS. 43A to 43C illustrate schematically simulated falls and block distribution diagrams and voltage output tests of a piezoelectric panel incorporated into a smart knee pad in accordance with an embodiment.

FIG. 44 illustrates a comparison of x-ray diffraction patterns of various sensing materials.

FIG. 45 illustrates the experimental set up to test the piezoelectric properties of various embodiments.

FIG. 46 illustrates the experimental set up of cyclic impact tests of an exemplary embodiment.

FIGS. 47A and 47B illustrate the circuit diagram used for testing piezoelectric panels in accordance with various embodiments.

### DETAILED DESCRIPTION OF THE INVENTION

It will be understood that the components of the embodiments, as generally described herein and illustrated in the appended figures, may be arranged and designed in a variety of different configurations. Thus, the following more detailed description of various embodiments, as represented in the figures, is not intended to limit the scope of the present disclosure but is merely representative of various embodiments. While various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages and similar language throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment. Thus, the phrases “in one embodiment,” “in an embodiment,” and similar language throughout this specification may but do not necessarily, all refer to the same embodiment.

Turning to the drawings, schemes, and data, embodiments of piezoelectric composite materials with excellent mechanical strength and piezoelectric sensitivity, as well as methods for the fabrication thereof, and smart protective devices incorporating the same are provided. In many embodiments, the piezoelectric composite materials comprise a porous scaffold characterized by a bio-inspired structure, an irregular, cuttlebone-like inner-walls microstructure and comprising a plurality of voids and interconnected channels; and a Rochelle salt crystal filling the plurality of voids to an extent. In many embodiments, the porous scaffold is fabricated via a 3D-printing method. In many embodiments, the piezoelectric composite materials are healable and recyclable. In several embodiments, the piezoelectric composite material is incorporated into a panel, such that each panel is characterized by measurable piezoelectric properties. In many embodiments, the piezoelectric composite material is incorporated into a smart protective wearable device comprising a plurality of panels. In many embodiments, the smart protective wearable device is a device type selected from the group consisting of (but not limited to): armor, knee pad, and any combination thereof. In many embodiments, the piezoelectric composite materials are utilized in smart monitoring electronics for a variety of applications related to (but not limited to) sports, medicine, military, and aerospace; such as, for more specific examples (but not limited to), sports vests, space armor, and elderly protective gear.

### Piezoelectric Composite Material

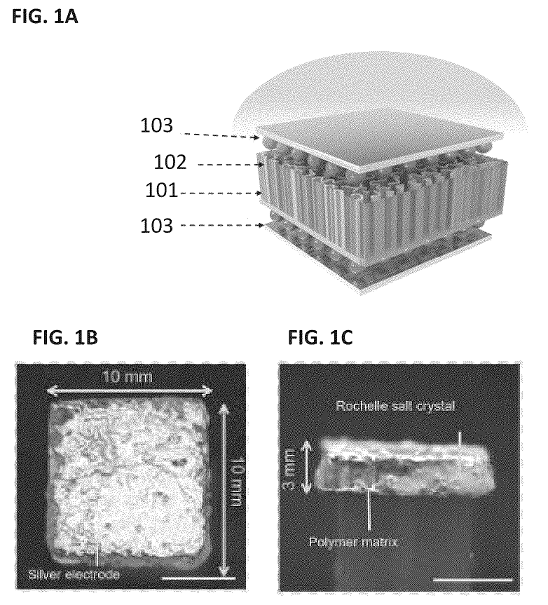

Piezoelectric composite materials in accordance with many embodiments produce an output voltage in response to a force. FIG. 1A provides an exemplary embodiment of a piezoelectric composite material comprising a polymer scaffold 101 and a sensing material 102, sandwiched between silver electrodes 103. FIG. 1B and FIG. 1C further provide an exemplary embodiment used for testing. In many embodiments, the polymer scaffold defines an irregular internal structure. The internal structure of many embodiments is defined by a plurality of interior walls and wall-septa. Wall-septa are internal walls that divide the interior of a structure. In various embodiments, the interior walls are arranged in an irregular pattern to define a plurality of channels and voids. In some embodiments, one or more interior walls interconnect to form a void, wherein a space is defined within the internal structure of the scaffold that is entirely surrounded by one or more interior walls. In several embodiments, one or more interior walls interconnect to form a channel, wherein a space is defined within the internal structure of the scaffold that is partially surrounded by one or more interior walls. In various embodiments, a channel may be interconnected with one or more additional channels such that the spaces defined by more than one channel are open to each other. In many embodiments, the pattern of the interior walls is irregular such that there is no repeatable pattern or a basic unit cell. In many embodiments, the interior walls are irregularly curved, bent, angled, and/or any combination thereof such that the channels and voids have an irregular surface area. In various embodiments, the irregular configuration of the interior walls is random such that surface area of the channels and voids varies within a single scaffold.

In many embodiments, the irregular internal structure of the scaffold provides structural support for the piezoelectric composite material. The irregular curves, bends, angles, and/or any combination thereof of the interior walls provide increased energy absorption from compressive forces than repeatable pattern scaffolds. The plurality of channels and voids provide the scaffold with increased damage prevention due to increased load distribution across the irregular interior walls.

In several embodiments, the sensing material comprises a crystallized material. In many embodiments, the sensing material is configured to grow within the irregular internal structure of the scaffold such that the sensing material crystallizes within the scaffold to form a fully crystallized sensing material. Due to the irregular configuration of the interior walls comprising irregular curves, bends, angles, and/or any combination thereof, the internal structure may comprise various irregular and random surface areas. The crystallization of the sensing material within the internal structure of the scaffold ensures the crystalized sensing material is adhered to the random and irregular surface areas. In many embodiments, this allows for the sensing material to substantially fill the internal structure of the scaffold. The piezoelectric composite material of various embodiments exhibits increased sensitivity due to the sensing material substantially filling the entirety of the internal structure of the scaffold.

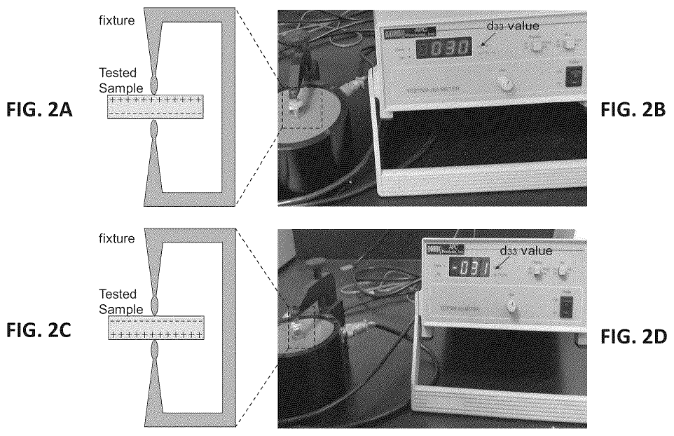

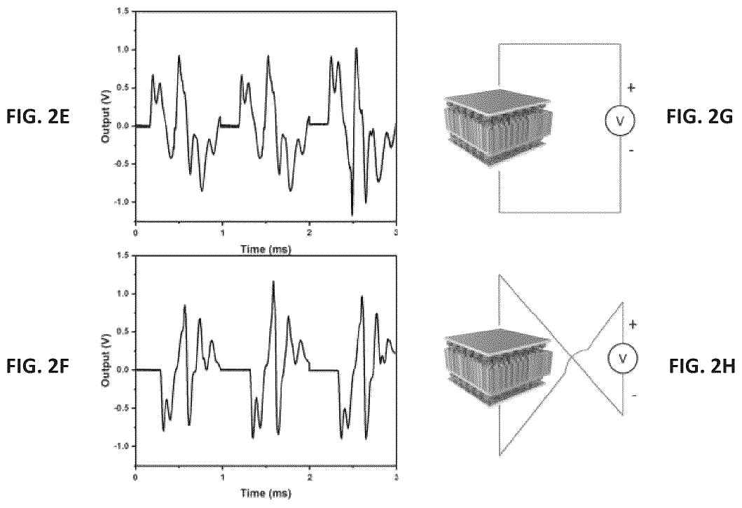

In many embodiments, the piezoelectric composite material demonstrates excellent piezoelectric output voltage under a relative low impact force. FIG. 2A and FIG. 2C schematically represent the piezoelectric charge of exemplary embodiments. FIG. 2B and FIG. 2D provide the piezoelectric coefficient d₃₃ measured by exemplary embodiments. In many embodiments, the measured voltage signals are a piezoelectric response based on observed piezoelectric response when the applied voltage was switched as shown in FIG. 2G and FIG. 2H. When the polarity is reversed, in many embodiments, the piezoelectric output curve is reversed, as shown in FIG. 2E and FIG. 2F.

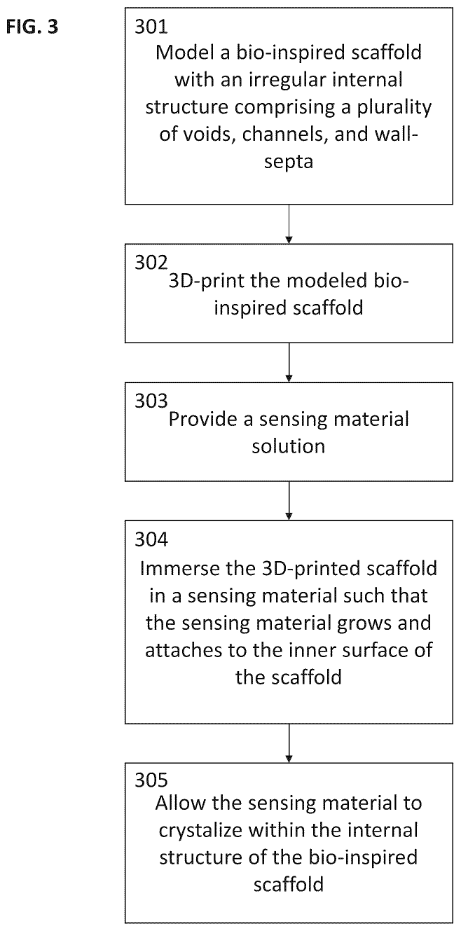

FIG. 3 provides the process of fabricating a piezoelectric composite material in accordance with several embodiments. In many embodiments, the piezoelectric composite material of many embodiments comprises a scaffold with an irregular internal structure. The scaffold comprising an irregular internal structure may be modeled in COMSOL Multiphysics 301. After the scaffold is modeled, it may be fabricated via additive manufacturing techniques, including but not limited to 3D-printing 302. The piezoelectric composite material of many embodiments comprises a sensing material 303. In several embodiments, the sensing material is a crystallized material. In some embodiments, the sensing material is configured to crystallize within the internal structure of the scaffold 304. The sensing material of various embodiments is configured to crystallize over a period of time to ensure the sensing material substantially fills the internal structure of the scaffold 305.

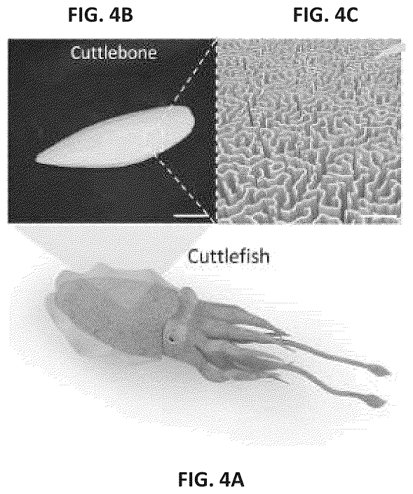

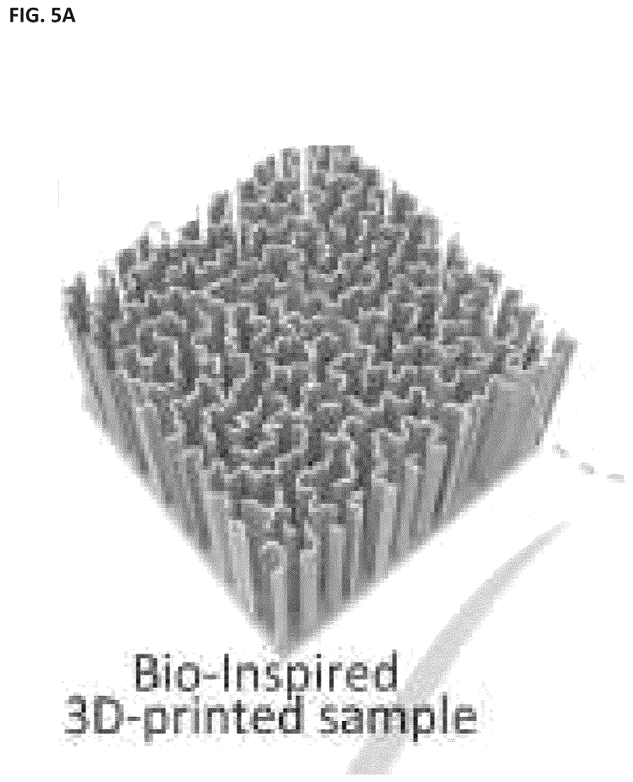

In many embodiments, the polymer scaffold 101 may be configured to have an irregular microstructure comprising a plurality of voids and interconnected channels. In some embodiments, the irregular structure is configured to resemble the microstructure of the bones of a cuttlefish. The polymer scaffold 101 may be configured to have an irregular shape resembling a cuttlefish bone-like microstructure. Natural biostructures have evolved over thousands of years to possess low density and high strength characteristics. FIG. 4A through FIG. 4C shows an example of a bio-inspired structure: the stiff and strong structure of the cuttlebone (FIG. 4B) in cuttlefish (FIG. 4A), wherein the cuttlebone has evolved to withstand high water pressure of the deep-sea. In particular, the uniquely chambered wall-septa microstructure (FIG. 4C) plays a vital role in the excellent performance of the cuttlebone in high-pressure environment by endowing it with rigidity and energy absorption/damage-resistance properties. Furthermore, the high porosity of the wall-septa microstructure, shown in FIG. 4C, provides an excellent model for multifunctional sensor designs in accordance with many embodiments, including configurations relying on piezoelectric composites, wherein the empty chamber spaces between each wall-septa structure may be filled with functional materials specific to sensing applications. In many embodiments, the irregular internal structure of the scaffold may resemble the microstructure of the cuttlefish bone.

Nevertheless, manufacturing and filling the voids of the high-porosity structures resembling those found in the cuttlebone is challenging. Traditional piezo-based materials (i.e., materials capable of generating an electric charge in response to applied mechanical stress) are difficult to manufacture in an irregular shape. For example, the traditional fabrication process for piezoelectric composites (such as 1-3 or 2-2 composites) includes the dicing-and-filling technique and molding process. Dicing-and-filling technology for 1-3 and 2-2 composites is one of the most common fabrication methods for piezoelectric composites. However, complex microstructure design hinders the further development of these conventional fabrication techniques. For example, the use of a 3D-printed barium titanate honeycomb structure filled with epoxy to produce a piezoelectric composite requires subsequent high temperature sintering, which is typically time-consuming and often sacrifices the resulting composite's performance.

On the other hand, additive manufacturing, also known as 3D-printing technology, has become an effective way of overcoming the barriers to fabrication of complex bio-inspired structures with reinforced mechanical and electrical properties. In many embodiments, one of the most common resin 3D printing processes, Digital Light Processing (DLP) produces durable, uniform, and leak-proof prototypes and final parts in a wide range of advanced materials characterized by delicate features and smooth surfaces.

In many embodiments, the piezoelectric composite materials resembling cuttlefish bone are fabricated using a 3D-printing process. Accordingly, in many embodiments, a 3D-printing method is first employed to produce the porous scaffold resembling the microstructure of the cuttlefish bone. Some embodiments comprise a 3D-printed porous scaffolds that are bio-inspired comprising an irregular microstructure further comprising a plurality of voids, channels, and wall-septa. In some embodiments, the 3D-printing method is a high resolution stereolithography. In some such embodiments, the high resolution stereolithography is Digital Light Processing (DLP).

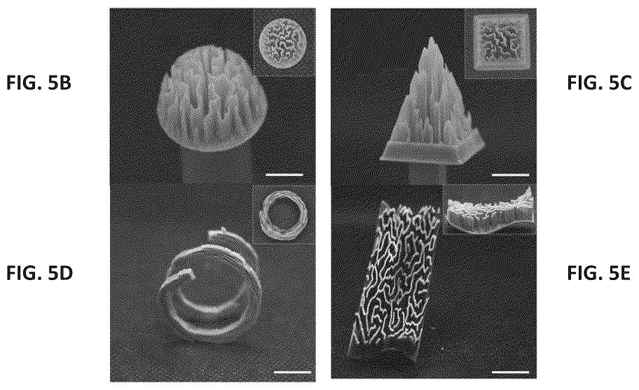

In many embodiments, the 3D printing process, including those disclosed herein, allow for fabrication of scaffolds in many different shapes and having different features with a variety of dimensions. FIG. 5A through FIG. 5E provide a number of complex shapes that the scaffolds of the piezoelectric composite materials may be 3D-printed to have in accordance with many embodiments.

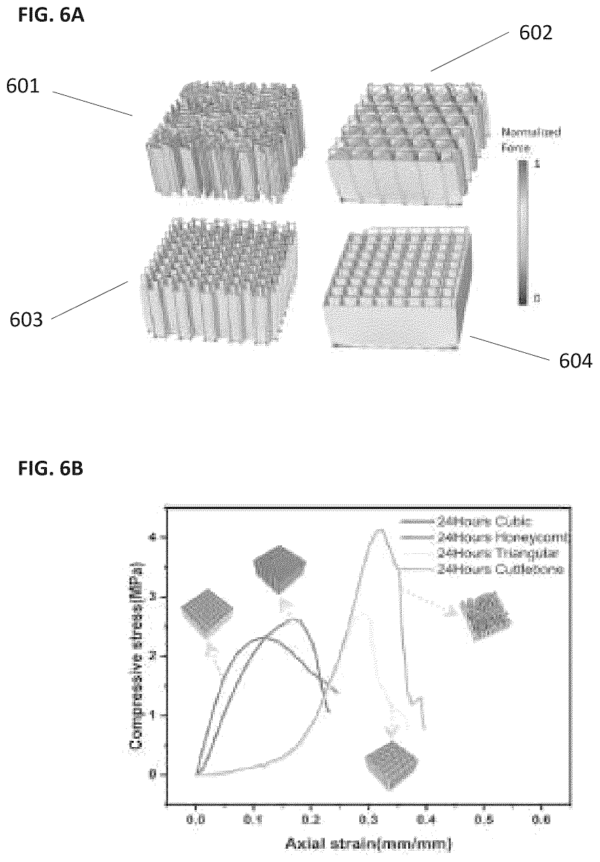

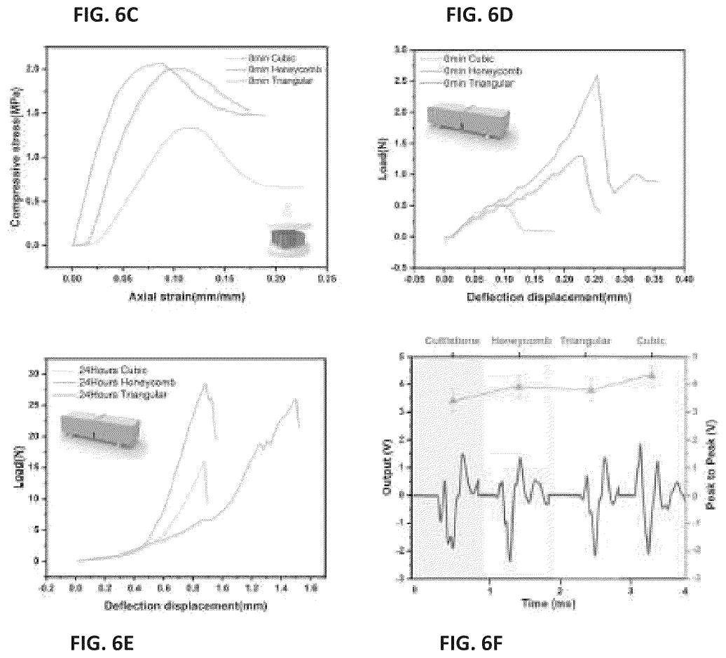

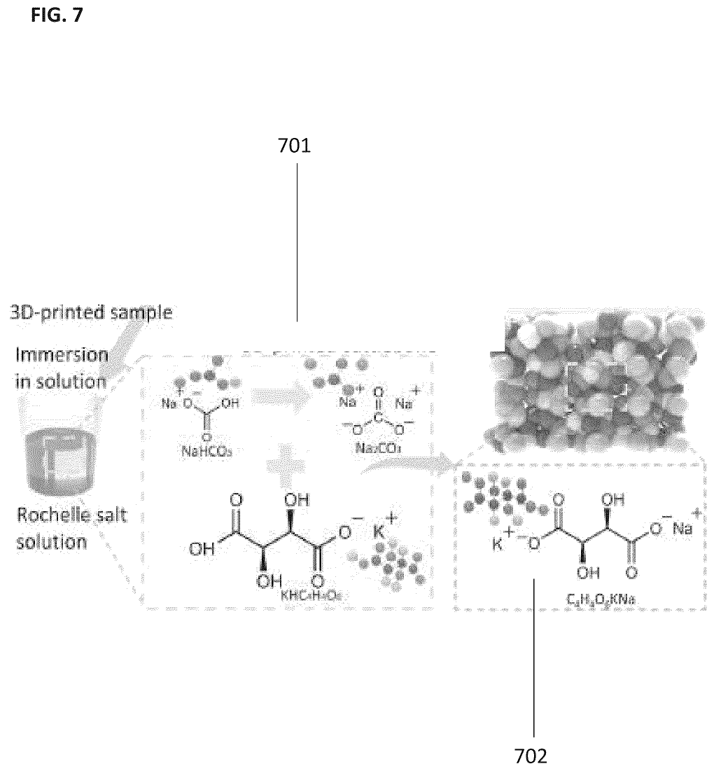

In many embodiments, the piezoelectric composite material possess excellent mechanical properties. In several embodiments, the bio-inspired irregular microstructure provides improved mechanical properties of the piezoelectric composite materials over scaffolds with different microstructures commonly known to possess good mechanical properties as shown in FIG. 6A. The bio-inspired irregular microstructure 601 is compared to a triangular microstructure 602, a honeycomb microstructure 603, and a cubic microstructure 604. FIG. 6A provides the force distribution of the various scaffolds subjected to compressive force, showing the bio-inspired irregular microstructure 601 exhibited uniform force distribution and the least deformation.

FIG. 6B through FIG. 6F compare the mechanical and piezoelectric properties of the various 3D printed scaffolds. The standard three-point bending tests with a notch may be conducted to determine the toughness of the materials of many embodiments, and all samples may be 3D-printed to have the identical dimensions (10 mm×5 mm×3 mm), with a notch depth of 0.6 mm. FIG. 6B compares the compressibility of the various scaffolds filled with a sensing material in accordance with some embodiments. FIG. 6C compares the load versus displacement for the four scaffold structures without a sensing material. FIG. 6D compares the compression force versus resistance change of the four scaffold structures without a sensing material. FIG. 6E compares the compression force versus resistance change for the scaffolds filled with a sensing material in accordance with various embodiments. FIG. 6F compares the output voltage of the scaffolds filled with a sensing material in accordance with many embodiments. In accordance with several embodiments, as provided in FIG. 6F, under the impact of the 2 g weight, the piezoelectric output of the piezoelectric composite material with the bio-inspired scaffold microstructure does not significantly differ from that of the three other composite materials, and, in fact, it is even approximately 20% lower. Nevertheless, the combination of the given satisfactory piezoelectric properties of the piezoelectric composite materials of many embodiments demonstrated above average and excellent mechanical properties making these materials preferred candidates for applications in protective piezoelectric sensors, such as, for example, a smart protective armor. Considering the advantages of the mechanically protective and piezoelectrical sensing abilities, the strong mechanical performance of the piezoelectric composite materials of many embodiments is a more significant material selection factor, than an outstanding piezoelectric performance, provided that the piezoelectric response is sufficient for a given application.

In many embodiments, the plurality of voids, channels, and interconnected channels of the irregular internal structure of the scaffold is filled with a sensing material to produce the piezoelectric composite material. The sensing material in accordance with many embodiments comprises a Rochelle Salt (RS). RS is an easily synthesized crystalline solid with expected piezoelectric and ferroelectric properties. Moreover, RS can be melted under relatively low temperatures (70-80° C.) and recrystallized after cooling. In addition, RS crystal is an eco-friendly material. Accordingly, RS shows great potential for utilization in sensing applications due to the ease of manufacturing, sustainability, and capability for self-healing.

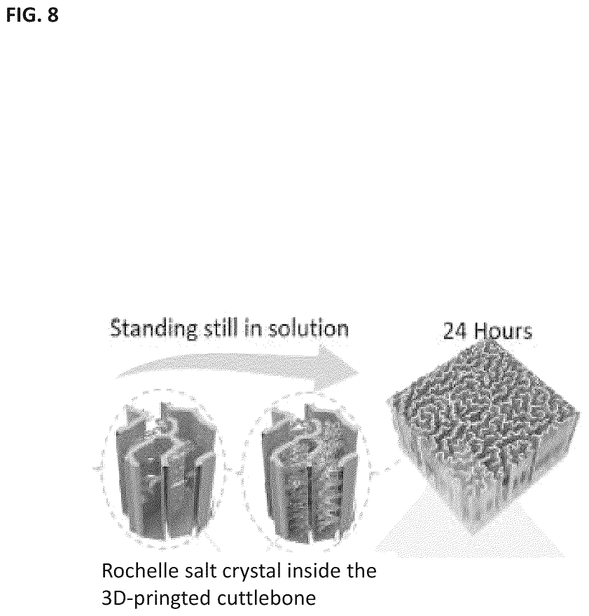

FIG. 7 schematically illustrates the chemical structure of an RS solution 701 and the final crystalized RS 702 sensing material. In many embodiments, the manufacturing process to produce the piezoelectric composite materials relies on the RS growth within the bio-inspired, 3D-printed, porous scaffold. In many embodiments, the fabrication methods comprise piezoelectric crystals grown into polymeric, 3D-printed, porous structures with complex shapes and feature different sizes and scales. FIG. 8 schematically illustrates the process of growing the RS crystal within the 3D printed bio-inspired scaffold while the 3D printed bio-inspired scaffold is immersed in the RS solution.

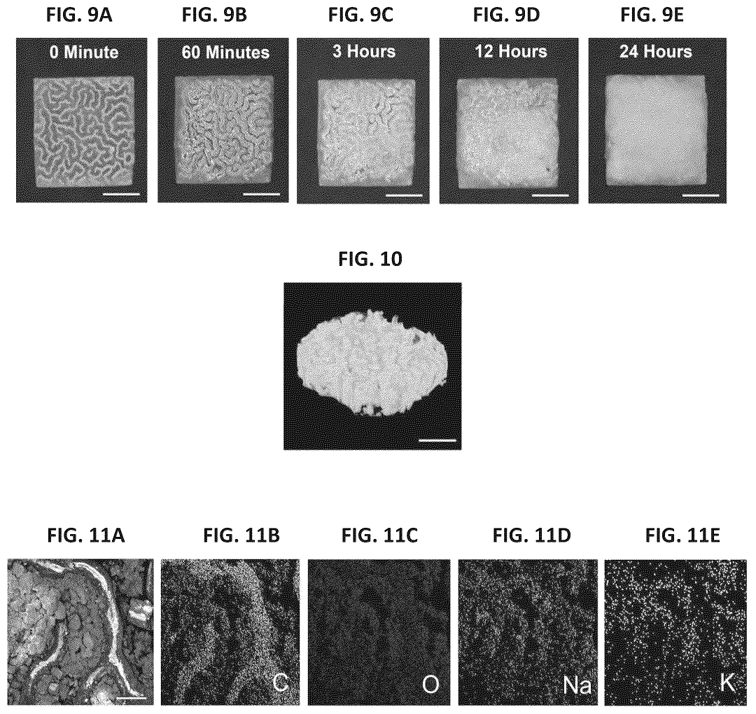

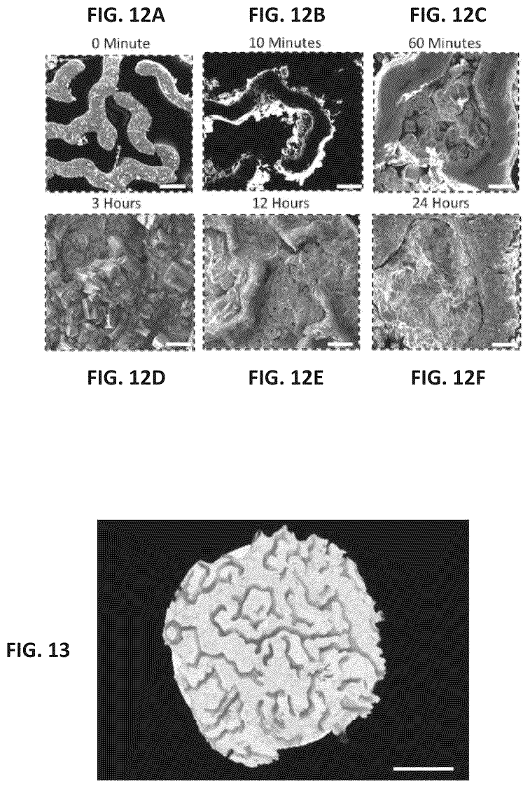

To fabricate the piezoelectric composite material, the RS crystal is allowed to grow over a period of time, in some embodiments for 24 hours. FIG. 9A through FIG. 9E provides digital photography snapshots of the process taken at the indicated times (0, 1 hour, 3 hours, 12 hours, and 24 hours) over a period of 24 hours. FIG. 10 provides a computerized tomography scanning image of a sample of the piezoelectric composite material in accordance with an embodiment. FIG. 11A through FIG. 11E provide energy dispersive X-ray elemental analysis of a sample of the piezoelectric composite material in accordance with an embodiment. FIG. 12A thru FIG. 12F provide scanning electron microscopy images of the scaffold of the piezoelectric composite material in accordance with an embodiment taken at the indicated times (0 minutes, 10 minutes, 1 hour, 3 hours, 12 hours, and 24 hours) during the RS crystal growth fabrication period over 24 hours. FIG. 12A and FIG. 12B have a scale bar of 600 μm, FIG. 12C has a scale bar of 500 μm, FIG. 12D has a scale bar of 200 μm, FIG. 12E has a scale bar of 600 μm, and FIG. 12F has a scale bar of 200 μm. As shown in FIG. 9A thru FIG. 12F, the RS crystal gradually grows along the walls of the scaffold from the outside inward, with noticeable RS crystal growth forming along the scaffold's wall after approximately 10 minutes, and each individual crystal having an 8-sided prism shape. Furthermore, a gradual increase in volume of each RS crystal is observed with increasing time, wherein the cross-sectional length of individual crystals reaches approximately 50 μm after 3 hours after the scaffold's immersion in the RS solution. However, after the RS crystals have been allowed to grow within the scaffold for 12 hours, in accordance with many embodiments, the growth of the crystals becomes so dense that it is impossible to distinguish the form of individual crystals. Eventually, according to many embodiments, after 24 hours, the RS crystals fill the entirety of the void portions of the bio-inspired scaffold and become interconnected with one another, as shown in FIG. 9E, FIG. 11E, FIG. 12F, and FIG. 13. FIG. 13 provides another computerized tomography scanned photo of a piezoelectric composite material in accordance with an embodiment after 24 hours of the RS crystal growth within the 3D printed bio-inspired polymer scaffold, wherein the scaffold comprises 20% of the piezoelectric composite material in accordance with an embodiment. In particular, FIG. 13, which illustrates the distribution of the 3D-printed structure and RS crystal growth, shows that the shape of the 3D-printed scaffold is completely filled with RS crystal after 24 hours of the RS growth. Moreover, the growth of the RS crystal filling the voids of the scaffold is uniform and dense.

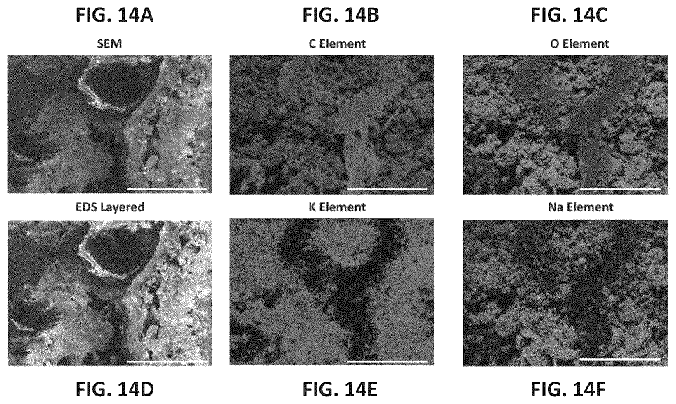

FIG. 14A through FIG. 14F provides SEM and energy dispersive X-ray spectroscopy (EDS) of the 3D-printed piezoelectric composite material of many embodiments that further characterize the microstructure and composition of such composites. More specifically, the carbon element is concentrated in the 3D-printed scaffold by virtue of the light-curing resin used in its fabrication, while oxygen, potassium, and sodium elements are mainly concentrated in the scaffold's voids filled with the RS crystal growth.

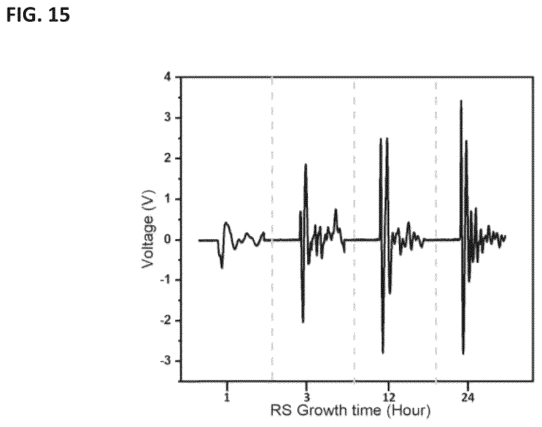

FIG. 15 provides the voltage output produced by a piezoelectric composite material with different lengths of RS crystal growth time in accordance with various embodiments. As shown in FIG. 15, the voltage output produced increases as the length of RS growth time increases.

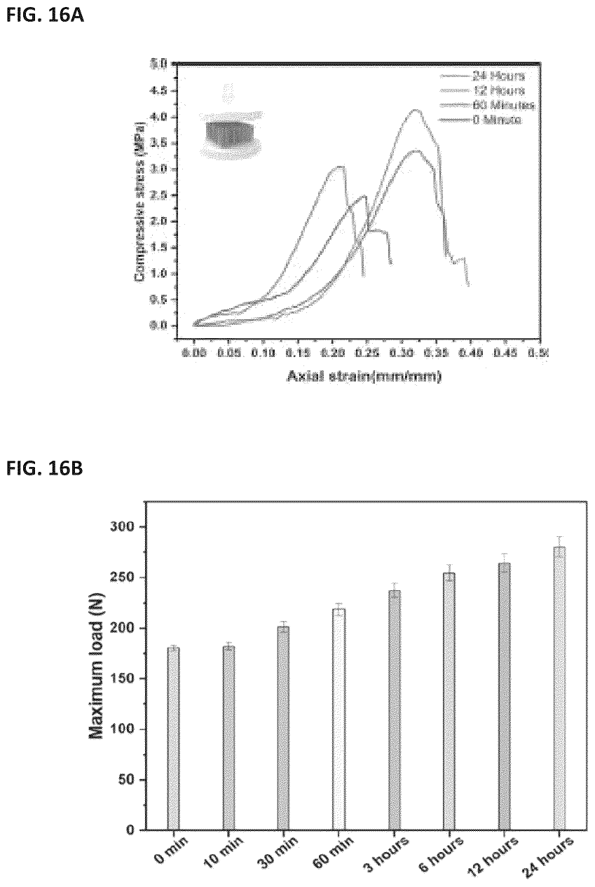

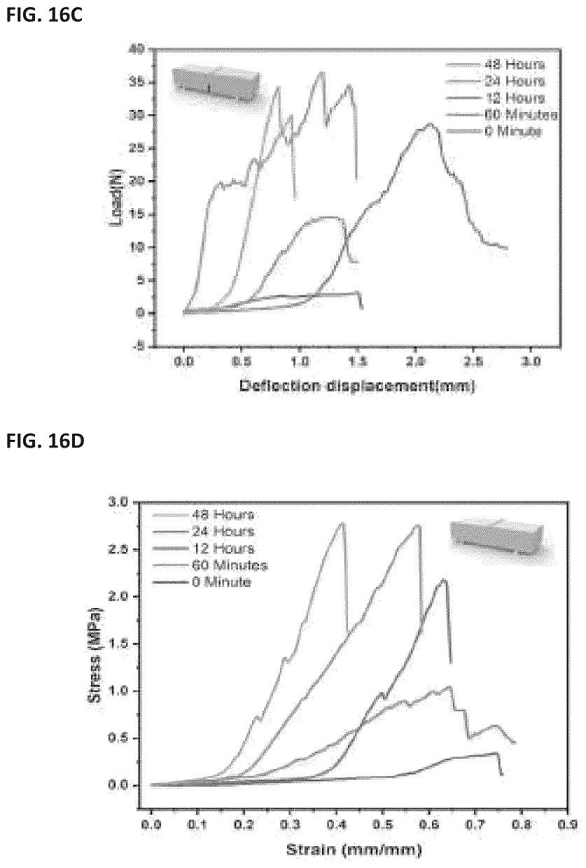

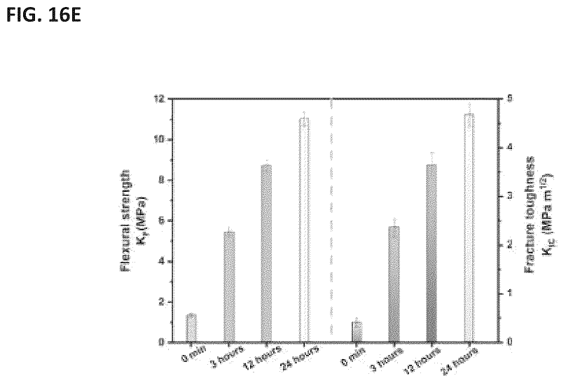

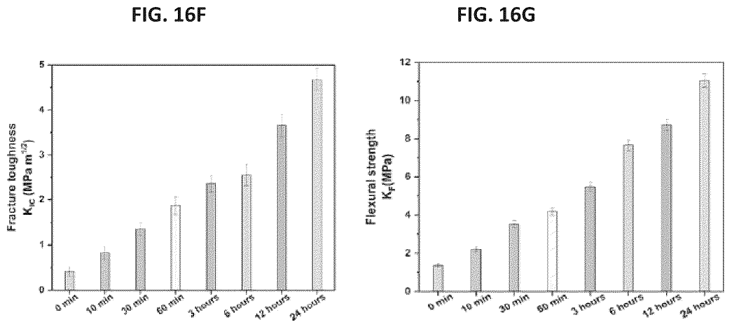

FIG. 16A through FIG. 16G illustrates the comparison of the mechanical properties of different piezoelectric composite materials with different RS crystal growth times. FIG. 16A compares the compressive stress-strain curves for the piezoelectric composite materials, in accordance with various embodiments, comprising the same bio-inspired microstructure scaffold but different amounts of the RS crystal fill, due to different RS solution exposure (RS crystal growth) times for the scaffold, and demonstrates a buffer downtrend. FIG. 16B provides a bar chart comparing the maximum loads (i.e., the load at failure) for the piezoelectric composite materials, in accordance with various embodiments, comprising various amounts of the RS crystal (bio-inspired scaffold exposed to the RS solution for different durations of time). As seen from FIG. 16B, as the RS crystal fills the porous bio-inspired scaffold of many embodiments (growth time increases), the maximum load value for the composites increases. Therefore, the RS crystal within the bio-inspired scaffold of many embodiments is a critical element for the piezoelectric composite materials' crack deflection and energy dissipation abilities. In several embodiments, the maximum load value gradually stabilizes once the bio-inspired scaffold's exposure time to the RS solution exceeds 24 hours, as seen in FIG. 16C and FIG. 16D. However, the RS crystals that have been grown within the bio-inspired scaffold for 24 hours increase the maximum load that the piezoelectric composite material of various embodiments can withstand by nearly 30% as compared to the same scaffold without the RS crystals. The bare bio-inspired scaffold already demonstrates a very high maximum load of 180N (due to the irregular bio-inspired wall-septa microstructures, wherein the wavy wall-septa limit damage to the internal chambers when under high pressure). As such, the RS crystals are believed to have satisfactory mechanical properties by themselves, and appear to contribute substantial mechanical protection to the piezoelectric composite materials of many embodiments.

FIG. 16C further illustrates the importance of the RS crystal fill for the toughness of the piezoelectric composite materials of many embodiments by providing plots obtained in standard three-point bending tests applied to composite materials with varying amount of the RS crystal fill due to different RS crystal growth times in accordance with various embodiments. A bare bio-inspired scaffold in accordance with various embodiments exhibits a nearly linear elastic response, before an entire failure occurs, showing crack propagation on the fracture surface. However, the piezoelectric composite materials comprising the RS crystal growth of as little as 1 hr, in accordance with various embodiments, show crack deflection, which is enhanced by crack suppression mechanisms, resulting in increased toughness.

FIG. 16E through FIG. 16G provide insight into the reinforcement mechanisms, structural integrity, and reliability afforded by the RS crystal component of the piezoelectric composite materials in accordance with many embodiments. More specifically, fracture toughness is defined as the capacity of a material with cracks to resist fracture and, as such, plays an important role in the structural integrity and reliability of materials. FIG. 16E (right side) and FIG. 16F provide the fracture toughness data for the composite materials with varying amounts of the RS crystal fill due to different RS crystal growth times in accordance with various embodiments. The larger RS crystal amounts (longer RS crystal growth times), of many embodiments, lead to an increase in the fracture toughness (expressed through fracture toughness for crack initiation value-K_{IC}, describing resistance to crack initiation). In an exemplary embodiment, the highest K_{IC} value of 4.67 MPa m^{1/2}, observed for the piezoelectric composite material sample with the 24 hour RS crystal growth is a 1144.6% enhancement over K_{IC} value for the bare bio-inspired scaffold.

FIG. 16E (left side) and FIG. 16G also provide the flexural strength data obtained from three-point flexural tests the piezoelectric composite materials with varying amounts of the RS crystal fill in accordance with various embodiments. The flexural strength of a material, expressed through K_{F} values, describes a material's stress just before the material yields and fails in a flexural test. Accordingly, FIG. 16E (left side) and FIG. 16G show that the flexural strength (K_{F}) of the piezoelectric composite materials of various embodiments increases significantly with the increase in the RS crystal growth within the bio-inspired scaffold. In an exemplary embodiment, the K_{F} of 11 MPa observed for the piezoelectric composite material with the 24 hour RS crystal growth is as much as 8.4 times larger than 1.3 MPa measured for the bare scaffold. In addition, the stress-strain curves for the bare scaffold and the piezoelectric composite material samples with varying amount of the RS crystal are presented in FIG. 16D and show a sharp drop behavior.

### Proportion of Bio-Inspired Scaffold to Sensing Material Fill

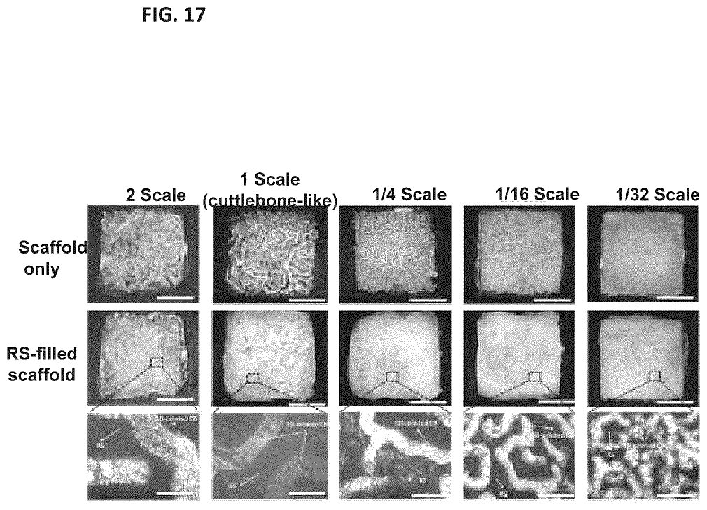

In an exemplary embodiment, the bio-inspired scaffold comprises 20% of the total volume of the piezoelectric composite material. FIG. 17 shows examples of the piezoelectric composite materials prepared according to the methods of many embodiments described herein to have different scaffold feature scales. More specifically, FIG. 17 shows samples of the piezoelectric composite materials prepared according to the methods of many embodiments to have varying scaffold feature sizes for electrical and mechanical comparisons, including a sample with the features scaled that most closely mimics the structure of the cuttlebone (2nd column). The scaling nomenclature relies on the premise that the volume of the 3D-printed bio-inspired scaffold is 20% of the total volume of the piezoelectric composite material, such that “2 scale” indicates a scaffold that is 2 times equal the scale enlargement, while “¼ scale” is ¼ of the scale, and so on. Moreover, as can be seen from FIG. 17, especially microscopy images in the bottom row, the RS crystals appear to be dense and uniformly distributed throughout the 3D-printed bio-inspired scaffold in all samples regardless of the scaffold's microstructure scale.

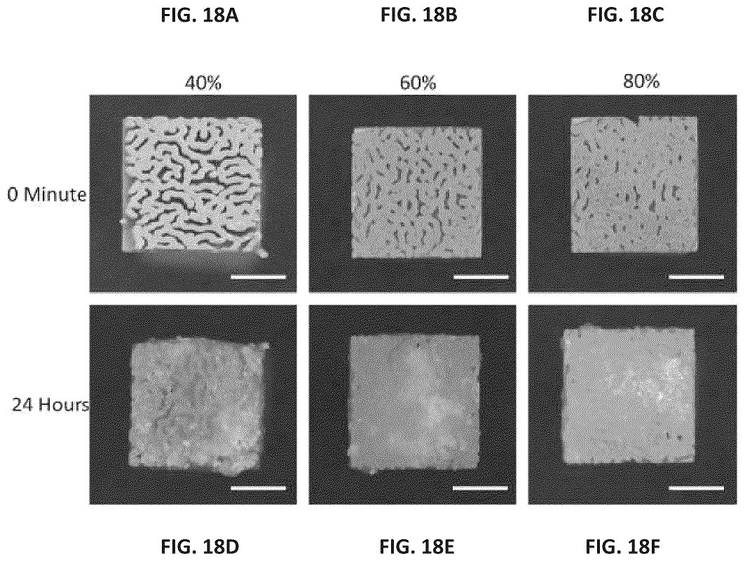

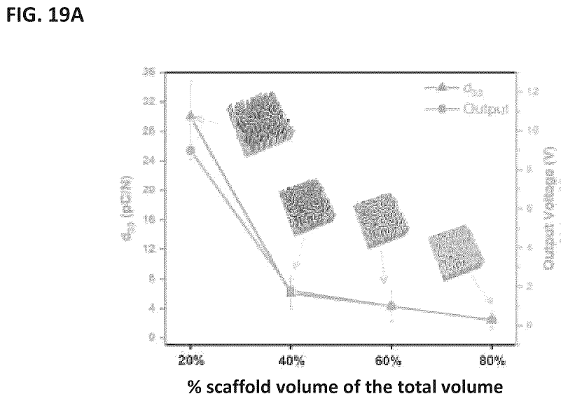

The piezoelectric composite materials of many embodiments may have different volume ratios of the polymeric scaffold, including but not limited to 20, 40, 60, and 80% of the total piezoelectric composite material volume. The piezoelectric response of the various scaffold ratios may be assessed and compared by applying stainless steel weight loads with weights ranging from 1 to 20 grams along the vertical direction. FIG. 18A through FIG. 18C provides images of bare bio-inspired scaffolds in accordance with various embodiments with different scaffold ratios of 40% (FIG. 18A), 60% (FIG. 18B), and 80% (FIG. 18C). FIG. 18D through FIG. 18F provide the bio-inspired scaffolds filled with RS crystals in accordance with various embodiments with different scaffold ratios of 40% (FIG. 18D), 60% (FIG. 18E), and 80% (FIG. 18F).

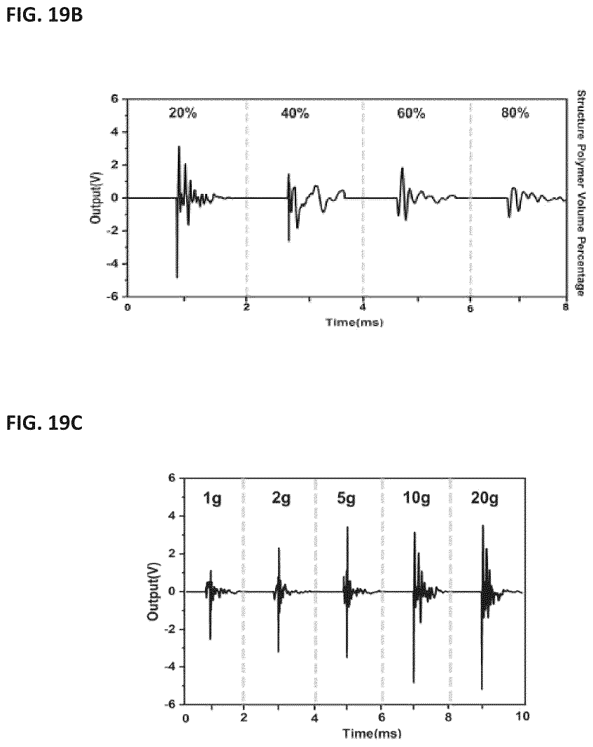

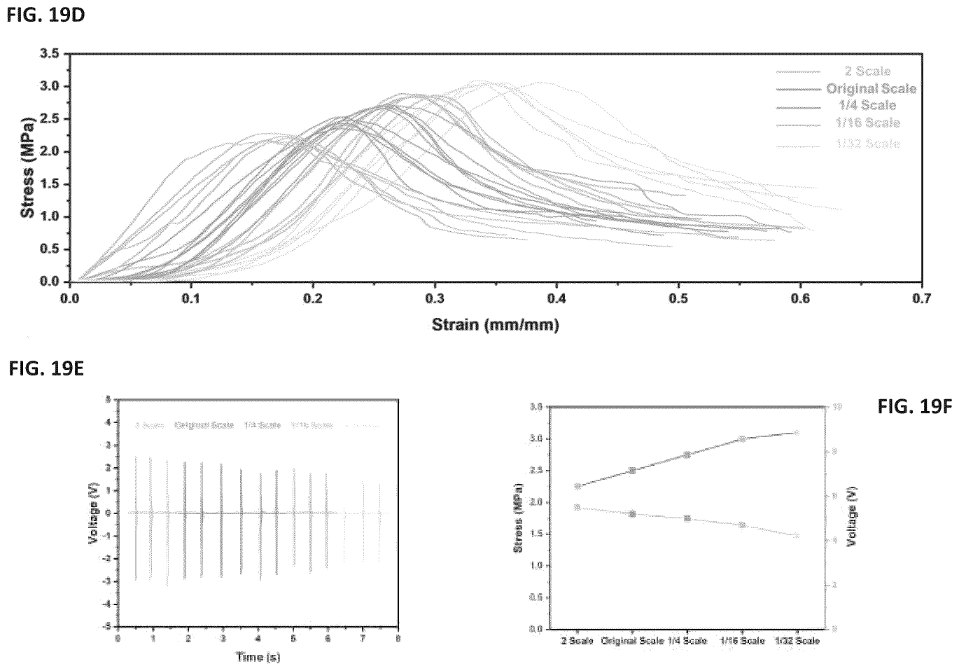

FIG. 19A compares the effective piezoelectric coefficient d₃₃, along with the voltage output, between the piezoelectric composite materials with varying volume ratios of the bio-inspired scaffold (at 20%, 40%, 60%, and 80% of the total piezoelectric composite material volume) in accordance with various embodiments. FIG. 19B provides that a sample of the piezoelectric composite material in accordance with many embodiments with the bio-inspired scaffold comprising 20% of the composite's volume demonstrates the highest output voltage performance in free fall tests with a 10 grams weight load, as compared to the other samples when the contact angle is 0°, owing to the contribution of the high-volume RS crystal ratio. Furthermore, significant differences in the output voltage can be observed for the 20% volume scaffold composite in accordance with an embodiment upon application of different weight loads as shown in FIG. 19C. In particular, dropping a 20 grams weight load from the distance (height) of 50 mm directly above such piezoelectric composite material of many embodiments produced a voltage output of as high as 8 Vₚₑₐₖ₋ₚₑₐₖ.

In addition, FIG. 19D through FIG. 19F, illustrate the piezoelectric performance of the piezoelectric composite materials of many embodiments having the same volume ratio of the scaffold (here, 20%), but different scaffold feature scales. More specifically, FIG. 19D provides the relationship between the scaffold's microstructure scale size and the compression properties. FIG. 19E provides the piezoelectric output under 2 Hz frequency. FIG. 19F provides the relationship between stress and peak-to-peak output voltage (error bars represent standard deviation (n=10)).

### Piezoelectric Properties of a Bio-Inspired Piezoelectric Composite Material

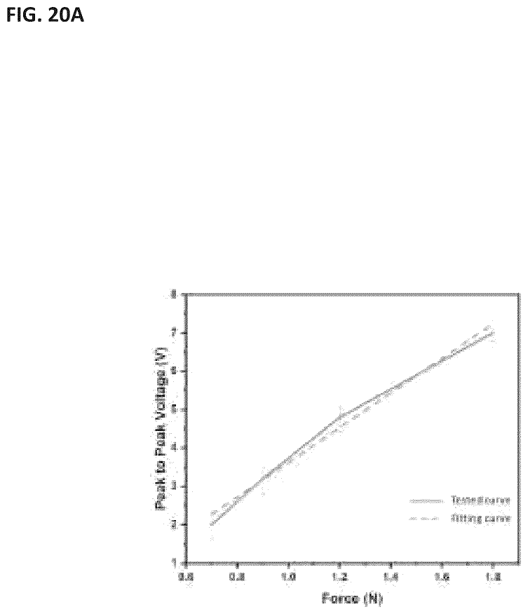

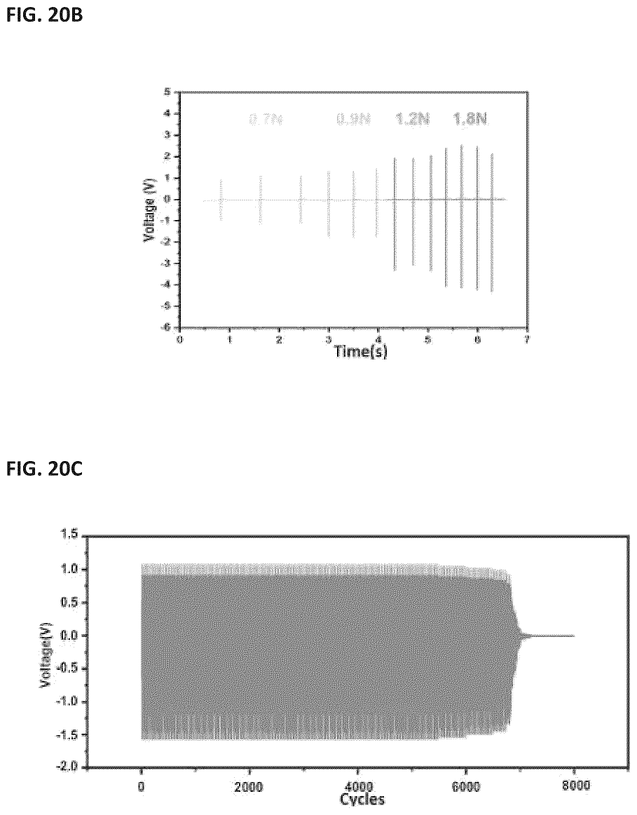

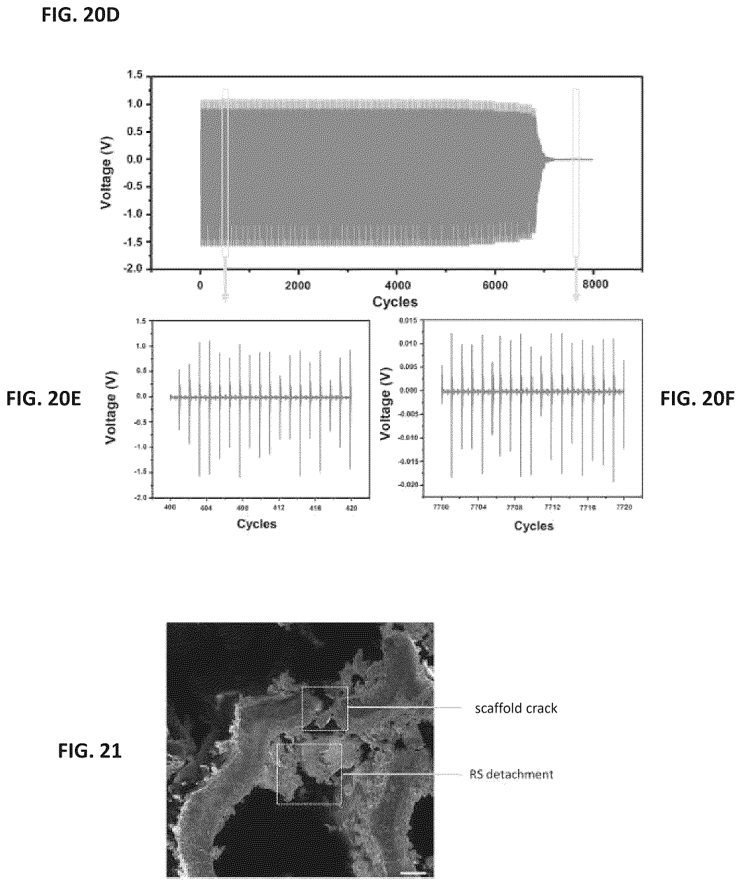

The piezoelectric performance of several embodiments was further obtained by cyclic tests. FIG. 20A through FIG. 20F provide the results of the cyclic force tests as applied to several embodiments. FIG. 20A provides the sensitivity of piezoelectric composite materials in accordance with many embodiments by the peak-to-peak output voltage under varying forces. FIG. 20B provides how voltage is generated by continuous impact on piezoelectric composite materials in accordance with several embodiments from 1 Hz to 4 Hz. FIG. 20C and FIG. 20D provide the 8000 cycles cyclic impact test output voltage, indicating that, in many embodiments, the devices comprising the piezoelectric composite materials perform well and maintain a stable output voltage from 0 to 6800 impact cycles. FIG. 20E provides a zoomed in voltage output for cyclic impact testing between cycles 500 and 520. FIG. 20F provides a zoomed in voltage output for cyclic impact testing between cycles 7700 and 7720.

FIG. 21 provides a scanning electron microscopy image of a fracture of the piezoelectric composite material in accordance with an embodiment was observed at about 6800 cycles with RS crystal detachment. A complete failure of the piezoelectric composite material in accordance with an embodiment occurred at approximately 7000 cycles, as shown in FIG. 20D and FIG. 20F. However, an ability to withstand a cycling of 7000 impacts is a sufficient strength characteristic for material applications such as, for example, an athlete's smart armor for use in a single sport season. Furthermore, in the event that the piezoelectric composite material, in accordance with an embodiment, has been damaged, the healable and recyclable characteristics of the piezoelectric composite materials of many embodiments, allow for their facile repair and continued use, as discussed elsewhere in the instant disclosure.

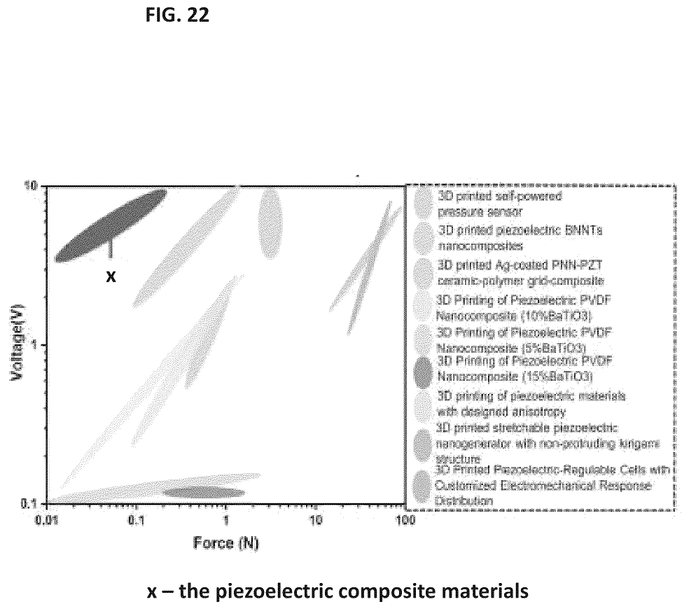

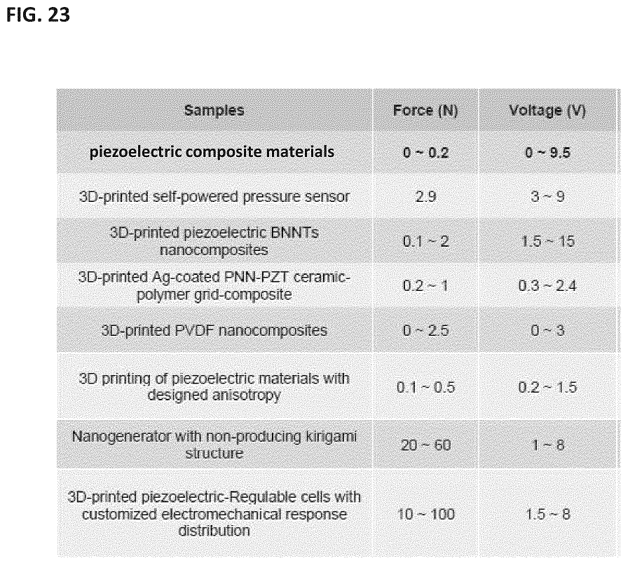

In turn, FIG. 22 and FIG. 23 compare the piezoelectric composite materials, in accordance with several embodiment, to various other piezoelectric materials reported to date, based on the amount of voltage output afforded by such materials in response to a magnitude of the applied force. As such, the comparisons further underscore the unprecedented sensitivity and responsiveness of the piezoelectric composite materials of many embodiments.

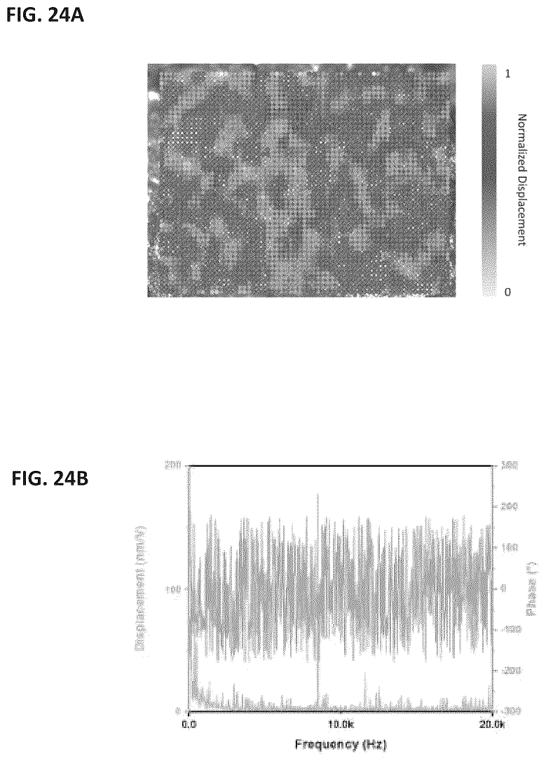

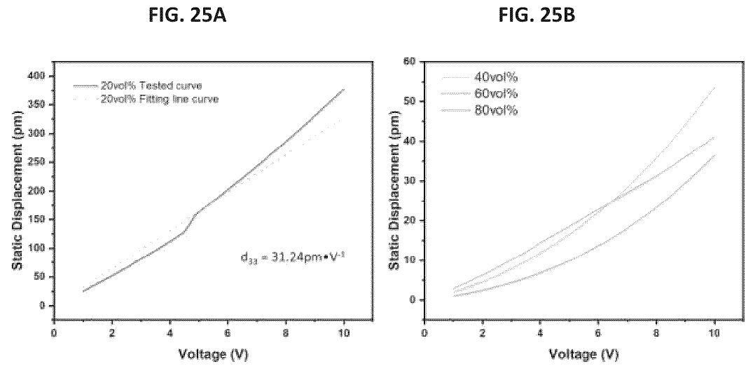

In many embodiments, the piezoelectric composite materials also demonstrate the converse piezoelectric effect, wherein the displacement is achieved under a voltage input. Accordingly, FIG. 24A illustrates the normalized out-of-plane displacement distribution, wherein red color signifies greater displacement change than the green color, corresponding to the locations of the RS crystal filling and the scaffold, respectively, within the piezoelectric composite material of an embodiment. Furthermore, FIG. 24B confirms that the piezoelectric composite materials, in accordance with several embodiments, exhibit a converse piezoelectric behavior, based on their dynamic response in the frequency domain. The statistical displacement increases with the applied voltage, and, as such, the slope of the linearly fitted resulting curve shown in FIG. 25A and FIG. 25B is the converse d₃₃. The direct and converse d³³ values for the piezoelectric composite materials of many embodiments remain essentially the same.

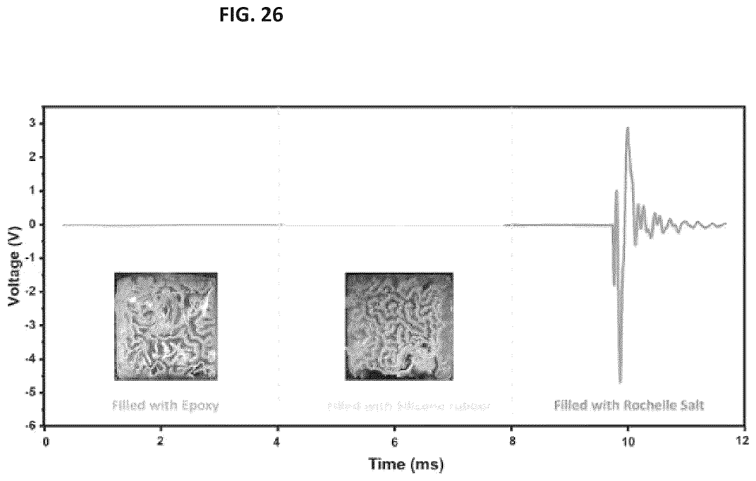

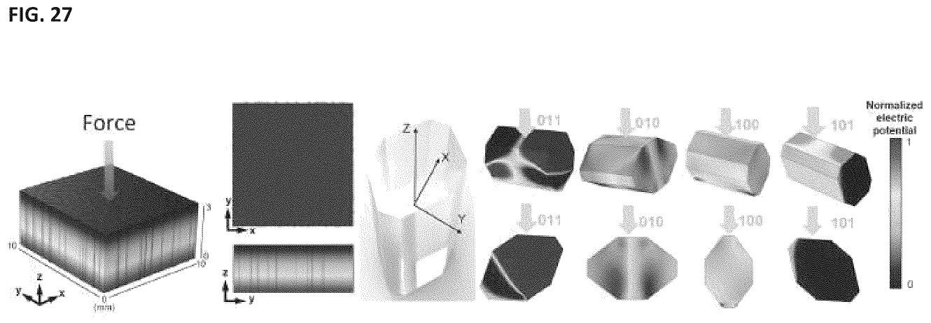

The piezoelectric responses (output voltages) from composite materials wherein the scaffold voids were filled with materials other than RS were also obtained and compared to that of the piezoelectric composite materials of many embodiments. FIG. 26 shows such experimental results wherein the scaffold of many embodiments was filled with either epoxy or silicone rubber, in addition to RS crystals. In many embodiments, the RS is a critical component for the piezoelectric response of the piezoelectric composite materials, as neither epoxy, not silicone rubber composites produced any detectable voltage output on impact the weights, in stark contrast to the piezoelectric composite materials.

FIG. 27 provides a structural finite-element-method simulation using COMSOL Multiphysics. A piezoelectric potential distribution occurs when a weight load falls or impacts perpendicularly to the piezoelectric composite material of many embodiments. From a linear electrochemical connection between mechanical and electrical conditions, piezoelectricity can be observed as a form of electricity. The piezoelectric coefficient dₖₘ (m/V) is a known constant for this linear relation, used to convert mechanics into electricity, namely from stress-strain to potential difference and electric field strength according to Equation 1 and Equation 2.

$${D}_{k} = {d}_{km} {T}_{m} \qquad ( EQ . 1 )$$

$${S}_{m} = {d}_{km} {E}_{k} \qquad ( EQ . 2 )$$

The linear electrical behavior of a material is related to the electric displacement Dₖ (C/m²) and electric field component Tₘ (V/m), while the strain component Sₘ (N/m²) and the stress component Tₘ (N/m²) correspond to Hooke's law for elastic materials. Furthermore, the k indicates the electric displacement component in a Cartesian reference frame (x₁, x₂, x₃), whereas m=1, . . . , 6 indicates the mechanical stress or strain; and, wherein, m=1, 2, and 3 refer to the normal stresses corresponding to x₁, x₂, and x₃ respectively, while m=4, 5, and 6 represent the shear stresses S₂₃, S₁₃, and S₁₂, respectively. The reduced matrix notation for dₖₘ, commonly used to express both direct and reverse piezoelectric effects as expressed in Equation 3:

$${d}_{KM} = [ \begin{matrix}dET 11 & dET 21 & dET 31 \\ dET 12 & dET 22 & dET 32 \\ dET 13 & dET 23 & dET 33 \\ dET 14 & dET 24 & dET 34 \\ dET 15 & dET 25 & dET 35 \\ dET 16 & dET 26 & dET 36\end{matrix} ] = [ \begin{matrix}0 & 0 & 0 \\ 0 & 0 & 0 \\ 0 & 0 & 0 \\ 3.45 {e}^{- 10} & 0 & 0 \\ 0 & 5.4 {e}^{- 11} & 0 \\ 0 & 0 & 1.2 {e}^{- 11}\end{matrix} ] \qquad ( EQ . 3 )$$

The orientation of crystals can be determined by the coordinate system selected to simulate the piezoelectric potential distribution of different crystal orientations. The reference frame's x₁, x₂, and x₃ are specified in the simulation as X, Y, and Z axes, respectively, for each single RS crystal. FIG. 27 further provides that an individual RS crystal has four pairs of force surfaces along the z-axis, and also shows the normalized electrical potential difference calculated in accordance with an embodiment. Although RS crystals demonstrate strong piezoelectric effect, the piezoelectric properties of individual RS crystals vary with reference to the crystalline axes. A RS crystal comprises three axes—the electrical axis (x-x′), the mechanical axis (y-y′), and the optical axis (z-z′), and the slices may be cut into different shapes to a specific application, such as, for example, an expander or shear vibration plates. For no cuts, the effective d₃₃ of the final structure is the combination of the three shear piezoelectric constants. The effective d₃₃ of several embodiments has been measured to be approximately 30 pC/N, fitting within the theoretical range.

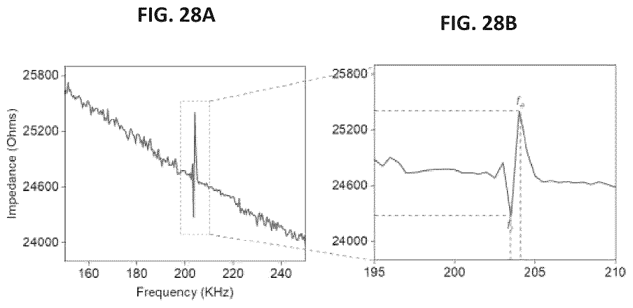

FIG. 28A and FIG. 28B provide electrical impedance spectrum data obtained from an impedance analyzer to determine the coupling factor for the piezoelectric composite material with a 20% scaffold volume in accordance with an embodiment. The electrochemical coupling coefficient (kₜ) of the piezoelectric material is defined according to Equation 4, wherein fᵣ is the resonant frequency, and fₐ is the anti-resonant frequency.

$${k}_{t} = \sqrt{\frac{π {f}_{r}}{2 {f}_{a}} \times cot \frac{π {f}_{r}}{2 {f}_{a}}} \qquad ( EQ . 4 )$$

FIG. 28B provides the resonant frequency and anti-resonant frequency can be located at 203.3 kHz and 204.2 kHz respectively, thus affording the coupling factor of 9.3%. The central frequency of the piezoelectric composite material of many embodiments is located between the resonant frequency and the anti-resonant frequency, with the impedance between 24300 ohms and 25400 ohms.

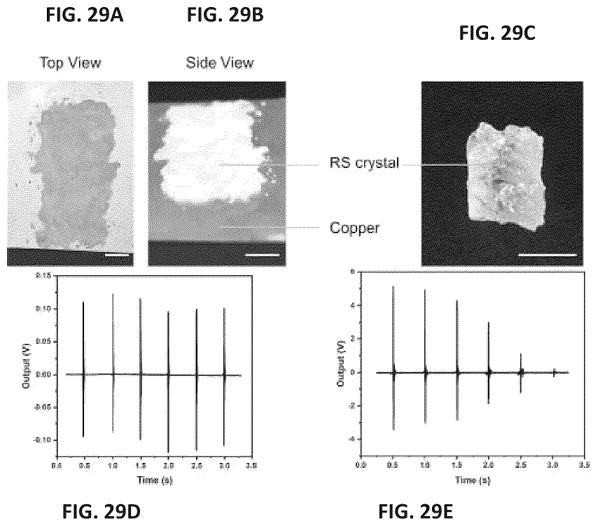

FIG. 29A thru FIG. 29E provide an analysis of the piezoelectric response afforded by a film of pure RS and a single RS crystal in accordance with various embodiments. In accordance with an embodiment, a piezoelectric RS film can be formed by dropping a solution of RS onto a copper sheet, with the copper sheet acting as both an electrode and a growing substrate, followed by attachment of an e-solder as the other electrode to the RS surface after 24 hours of RS growth as shown in FIG. 29A and FIG. 29B. FIG. 29D provides the output voltage obtained from subjecting the prepared RS piezoelectric film to a cyclic impact test at a frequency of 2 Hz. Pure RS crystals, as shown in FIG. 29C, were also subjected to the same cyclic impact piezoelectric testing and appear to be more fragile. FIG. 29D provides the pure RS crystals had greatly reduced response after only five cycles of impact testing. The 3D-printed, bio-inspired scaffold of many embodiments provides the mechanical support lacking in pure RS crystals, and, thus, is critical to the excellent piezoelectric properties of the instant piezoelectric composite materials.

The piezoelectric composite materials of many embodiments comprising RS crystals exhibit excellent piezoelectric properties without the need for any poling step. With three non-neglectable orthogonal piezoelectric coefficients in RS (d₁₄, d₂₅, d₃₆), piezoelectric responses can be measured in almost all axes except the optical axis (the longest tubular direction of crystals). RS crystals decompose at approximately 55° C.; and their polar ferroelectric phase, occurring at the Curie temperature range between −18° C. and +24° C., is monoclinic.

### Healable and Recyclable Piezoelectric Composite Material

In many embodiments, the piezoelectric composite materials are healable. More specifically, in many embodiments, damages caused to the RS crystal component of the piezoelectric composite materials are healable via heat-assisted recrystallization, wherein heating the RS crystal causes mature solid RS crystals to dissolve and revert to a liquid crystal solution phase and allows for re-crystallization of the damaged RS crystal component. The piezoelectric composite materials of many embodiments demonstrate excellent recyclability and sustainability, making them, according to many embodiments, ideal candidates for use in applications such as impact monitoring devices subjected to continuous impact.

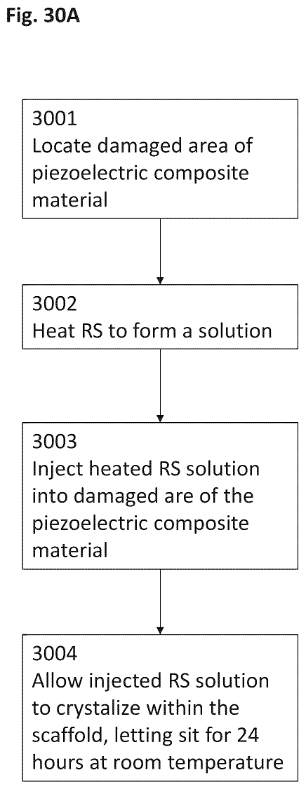

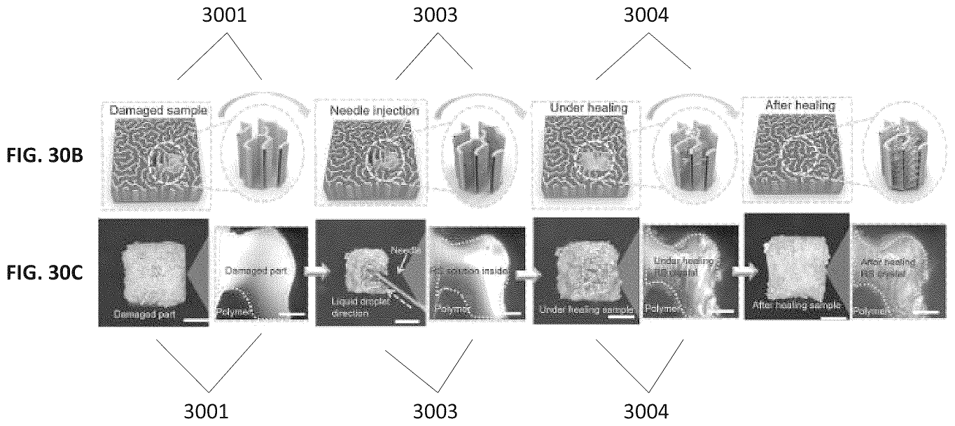

FIG. 30A provides the process to heal a damaged piezoelectric composite material in accordance with various embodiments. In many embodiments, a piezoelectric scaffold can be healed by first locating the damaged area 3001 where the RS crystal has disconnected from the bio-inspired scaffold. Next, new RS crystals are heated 3002 to form an RS solution. The heated RS solution is then injected into the identified damaged area of the piezoelectric composite material 3003. After injection, the RS solution crystalizes within the bio-inspired scaffold 3004. In some embodiments, the RS solution is allowed to crystalize at room temperature for 24 hours.

The healable properties of the piezoelectric composite materials of many embodiments are demonstrated in FIG. 30B and FIG. 30C. FIG. 30B schematically illustrates, after damage, the RS solution can be injected into the damaged area of a sample of the piezoelectric composite material and left at room temperature for 24 hours to heal. FIG. 30C provides microscope images showing that the RS crystal grows well within the scaffold, and that the damaged area is well healed after 24 hours.

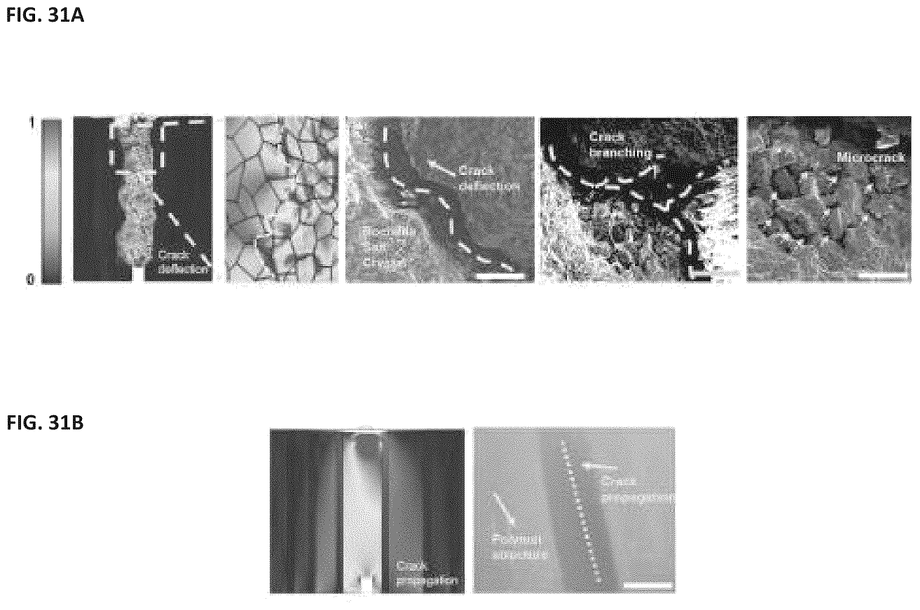

Furthermore, the healability of piezoelectric composite materials in accordance with many embodiments may be based on the crack branching and deflection between the RS crystal grain boundary (which is the crack suppression mechanism that absorbs energy and increases the fracture toughness) observed. FIG. 31A provides the observed crack branching and deflection of many embodiments. FIG. 31B provides the crack propagation mechanism of a bare bio-inspired scaffold, in accordance with an embodiment. As shown in FIG. 31A, the damage is not only confined to the crack tip in the piezoelectric composite materials but is also widely spread ahead of the growing crack by deflecting microcracks following the direction of the RS crystal growth within the bio-inspired scaffold of various embodiments.

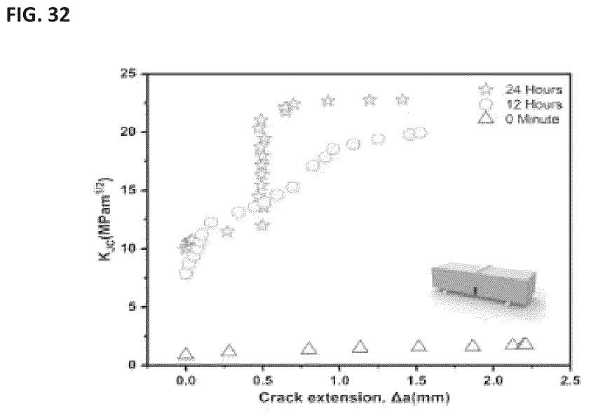

FIG. 32 further illustrates quantitative analysis of the changes in the fracture toughness K_{JC} with the crack extension Δα via the J-R curve approach. The characteristic crack resistance curve (R-curve) corresponds to the increase of K_{JC} with Δα. The piezoelectric composite materials comprising the RS crystal within the bio-inspired scaffold exhibit extensive rising R-curve behaviors. In various embodiments, the sample with the more extensive, 24 hour, RS crystal growth exhibits a higher R-curve than the composite with the 12 hour RS crystal growth, demonstrating that the scaffolds comprising a more extensive RS crystal growth are more effective at resisting a fracture during a crack propagation event. No R-curves were observed for the bare polymeric scaffold due to the crack propagation.

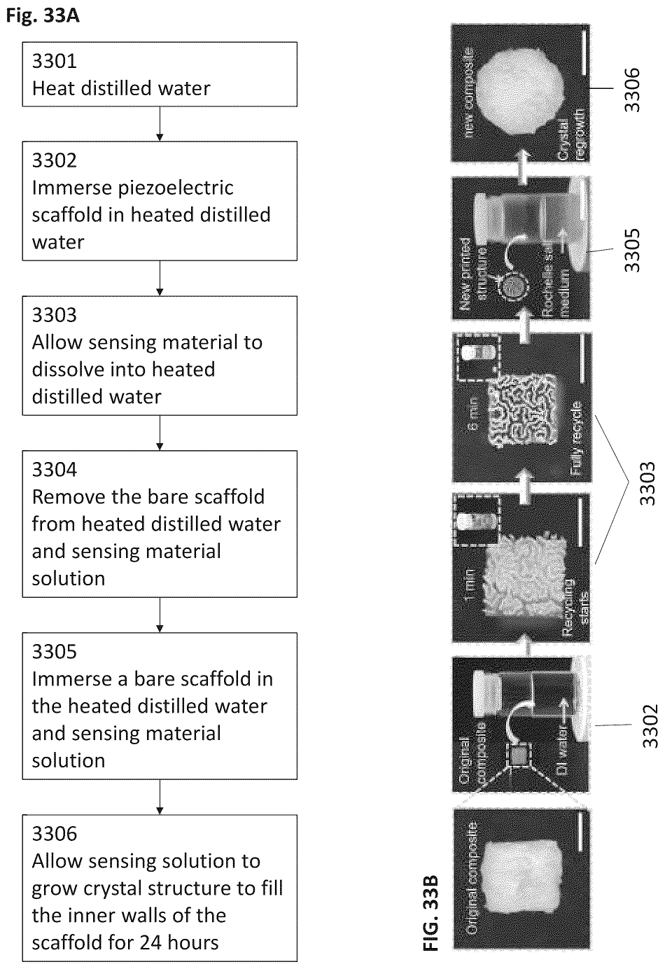

In many embodiments, the piezoelectric composite material is recyclable. FIG. 33A provides the process for recycling a piezoelectric composite material. The original piezoelectric composite material is immersed in heated distilled water 3301 such that the piezoelectric composite material is fully submerged 3302 in the heated distilled water. The sensing material dissolves into the heated distilled water such that the sensing material is removed from the bio-inspired scaffold 3303. Once the sensing material has been dissolved off the bio-inspired scaffold, the bare scaffold is removed 3304 leaving behind a sensing material solution in the distilled water. A different bio-inspired scaffold may then be submerged in the sensing material solution 3305. The sensing material is allowed to crystallize within the different bio-inspired scaffold 3306. In some embodiments the sensing material crystallizes within the different bio-inspired scaffold for at least 24 hours at room temperature.

In accordance with an embodiment, FIG. 33B provides a sample of the piezoelectric composite material first soaked in a vial containing heated distilled (DI) water 3302. After 6 min of immersion, the RS crystal inside the composite's scaffold is completely dissolved 3303, forming a heated RS solution in the DI water. Next, the bare polymeric scaffold of the sample is separated from the experimental solution 3304, and a new sample of the scaffold is immersed into the same RS solution 3305 for growth of the RS crystal within the new scaffold to afford a recycled sample of the same piezoelectric composite material 3306.

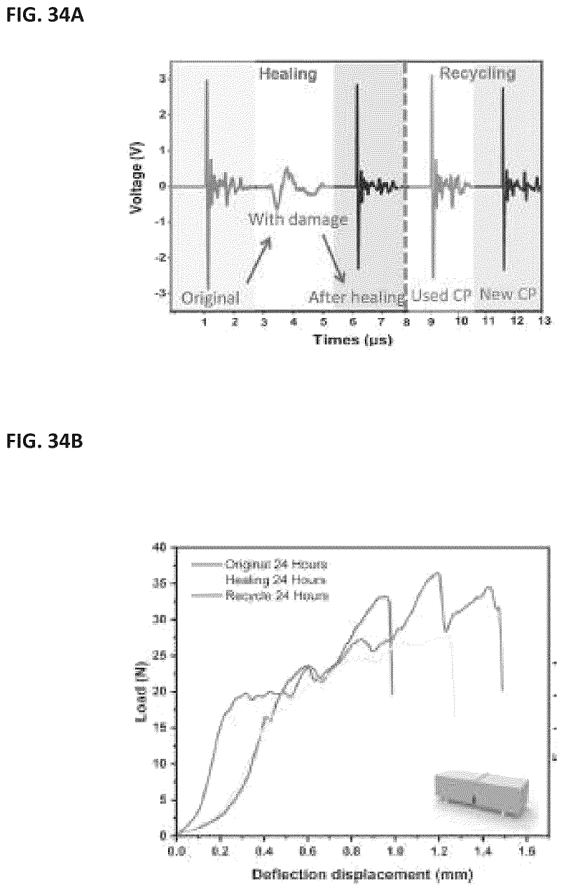

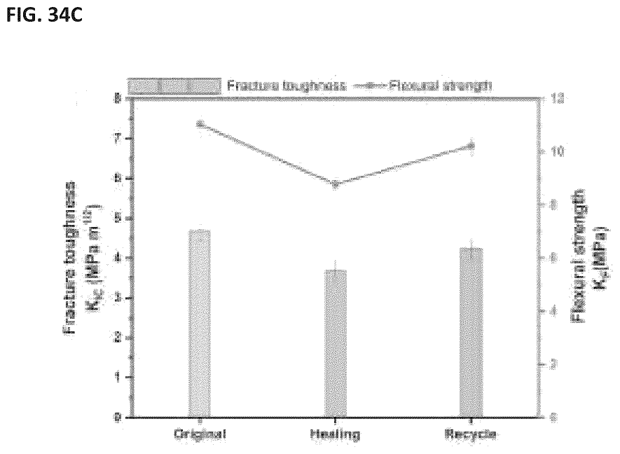

FIG. 34A through FIG. 34C provide various characterizations comparing the mechanical and piezoelectric performance of the healed and recycled samples of many embodiments to those of the original samples of the piezoelectric composite materials of many embodiments. FIG. 34A compares the elastic response and the amplitude of output voltage for the healed and recycled samples to that of the original sample. The healed and recycled embodiments demonstrate 95% of the original composite performance. FIG. 34B and FIG. 34C provide and compare the mechanical properties data obtained from subjecting all three samples, in accordance with various embodiments (original, healed, and recycled), to standard three-point bending tests. In many embodiments, the K_{IC} of the healed and recycled composites recover well, reaching 78.7% and 90.5%, respectively, of the original sample's K_{IC} value. Moreover, K_{F} of the healed and recycled samples achieved 79.5% and 92.6%, respectively, recovery, as compared to Kr of the original sample. In many embodiments, the RS crystal component of the piezoelectric composite materials can be easily healed and reused as needed for a given application. Accordingly, in many embodiments, the piezoelectric composite materials are highly sustainable and practical materials, suitable for a wide variety of applications, including, but not limited to smart armor and geriatric monitoring devices.

Piezoelectric Composite Material Incorporated into a Piezoelectric Panel

The following examples are put forth so as to provide those of ordinary skill in the art with a complete disclosure and description of how to make and use the present invention and are not intended to limit the scope of what the inventors regard as their invention nor are they intended to represent that the experiments below are all or the only experiments performed. Efforts have been made to ensure accuracy with respect to numbers used (e.g. amounts, temperature, etc.) but some experimental errors and deviations should be accounted for. Unless indicated otherwise, parts are parts by weight, molecular weight is number average molecular weight, temperature is in degrees Celsius, and pressure is at or near atmospheric.

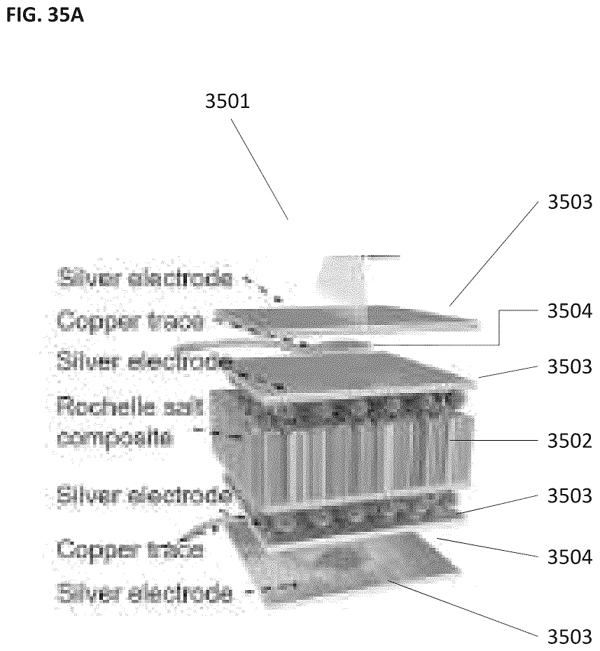

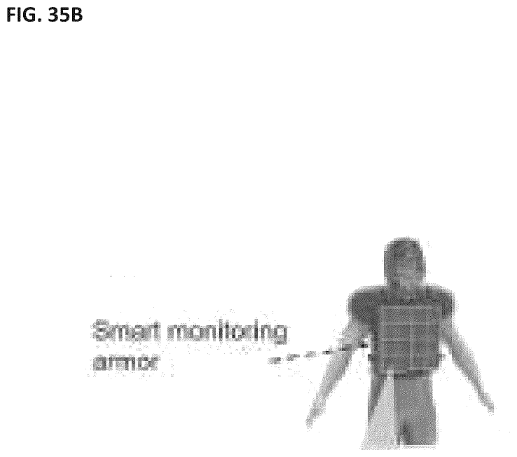

A piezoelectric composite material, in accordance with various embodiments, may be incorporated into a panel having superior piezoelectric properties and mechanical properties. FIG. 35A provides a schematic of a panel incorporating a piezoelectric composite material in accordance with an embodiment. The panel element 3501 comprises a bio-inspired scaffold with crystalized RS piezoelectric composite material 3502. The piezoelectric composite material 3502 is sandwiched between a silver electrode 3503, a copper trace 3504, and another silver electrode 3503. Multiple panel elements 3501 can be incorporated together in accordance with various embodiments.

### Body Armor

In many embodiments, the biomimetic, piezoelectric composite materials provide superior protection and remarkable piezoelectric sensing capabilities when used in a smart armor that provides integrated mechanical protection and electrical sensitivity for athletes. One example of such application, combining smart monitoring and protection, a smart armor comprising the piezoelectric composite material of many embodiments can be fabricated by 3D-printing and assembling a 4 by 4 panel construct comprising the bio-inspired scaffold, and immersing the construct into a RS solution for 24 hours. Subsequently, the smart armor can be attached to a football player model for testing as illustrated by FIG. 35B. It should be understood that the smart armor of many embodiments can be used for various applications, including but not limited to athletics, military, and aerospace. It should also be understood that the smart armor of various embodiments can be configured with varying panel construct including but not limited to 3 by 4, 4 by 5, 3 by 3, 7 by 6, and 8 by 8.

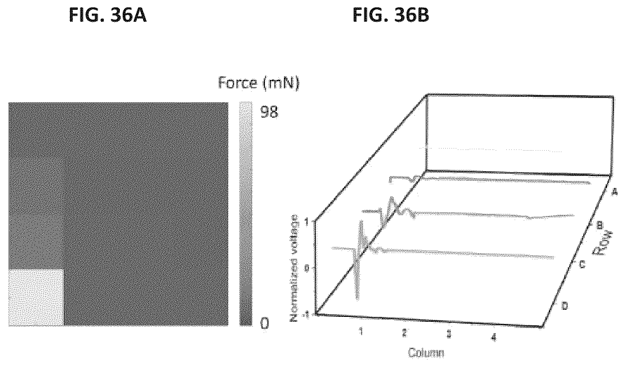

FIG. 36A and FIG. 36B provide piezoelectric test results of the smart armor in accordance with an embodiment. A 10 g weight is vertically placed onto the football player model wearing the smart armor. FIG. 36A provides the force magnitude distribution of an embodiment. FIG. 36B provides the piezoelectric output diagram, in accordance with an embodiment. More specifically, MATLAB may be used to analyze the magnitude distribution of force after uploading the piezoelectric output corresponding to each sensing element (4 rows by 4 columns of panels comprising the piezoelectric composite material for a total of 16 sensing elements in this embodiment). In FIG. 36A, the yellow color represents the element with the greatest force. In accordance with the magnitude distribution of the force, the higher the output piezoelectricity, the greater the force on the detection element.

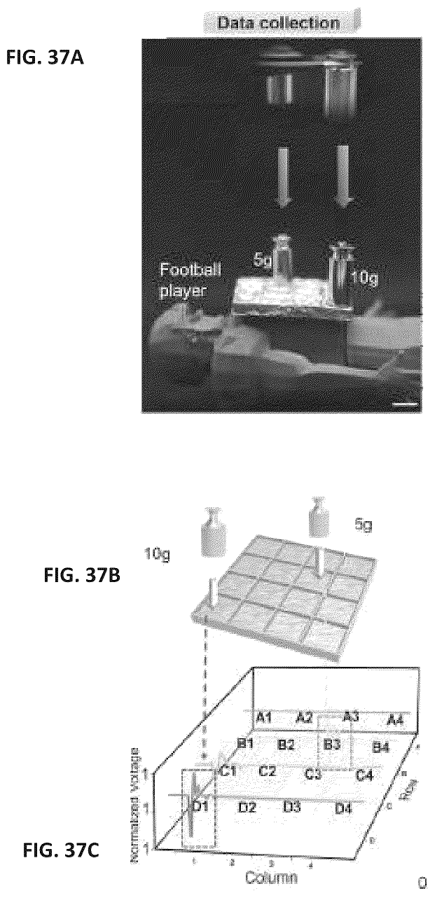

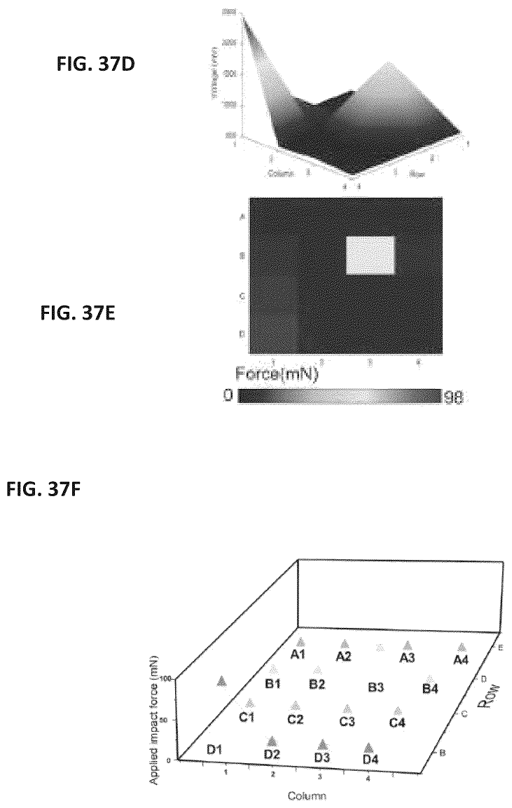

FIG. 37A through FIG. 37C illustrate a two weight test of body armor comprising piezoelectric panel of an embodiment. As illustrated in FIG. 37A, two weights of 5 g and 10 g are positioned on top of the panel at a distance of 5 cm from the surface of the smart armor. FIG. 37B schematically represents the location of the weights on the individual panel elements. FIG. 37C provides the corresponding voltage generated by each effected panel element. Furthermore, FIG. 37C provides the output voltage of nearby panel elements affected by the vibrations caused by the impact of the individual weights.

In several embodiments, the output voltage and piezoelectric effect is proportional to the magnitude of the force exerted on each panel element of the body armor. FIG. 37C provides a 3D visualization and FIG. 37E provides a 2D visualization of the force distribution for each panel element corresponding to the output piezoelectricity, in accordance with an embodiment during a two weight drop test.

FIG. 37F provides the output of the mechanical signals from all 16 panel elements of the smart armor in accordance with an embodiment during the two weight test, detected by means of flexible force sensors attached to the smart armor. As provided in FIG. 37F the mechanical signal derived from the output voltage signal is consistent with the measured physical impact input signal; and the high accuracy of the output voltage readings demonstrates the pressure on each panel element comprising the piezoelectric composite material of many embodiments. Accordingly, in many embodiments, the smart armor relying on the piezoelectric composite materials described herein allows for accurate positioning of the impact based on the different masses of the impacting object.

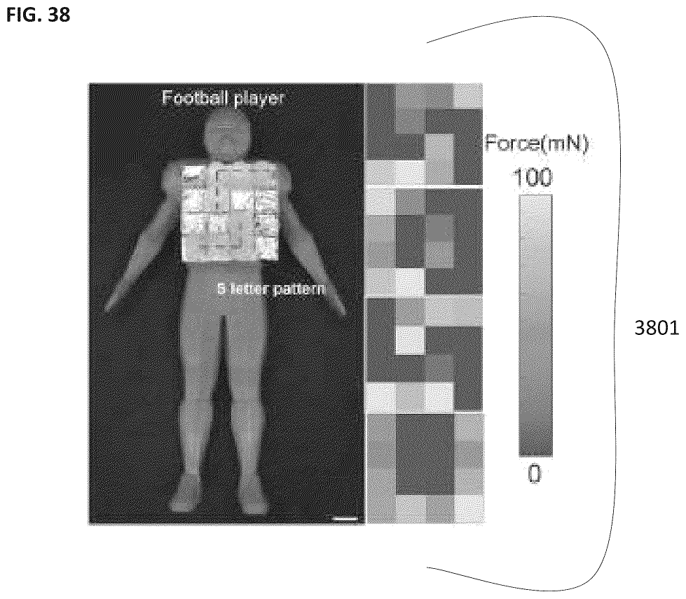

In addition, FIG. 38 illustrates another example of the impact detection and analysis by the smart armor of many embodiments. As provided in FIG. 38, 3D-printed letters S, D, S, and U were allowed to perpendicularly free fall from the same height of 20 cm onto the smart armor surface, and the resulting force analysis color blocking analyzed with the help of MATLAB. As such, according to the MATLAB color block analysis 3801, the letters were identified as S, D, S, and U, including determining each letter's shape and alignment, thereby providing, based on the generated voltage, the corresponding range of the forces impacting the smart armor. Accordingly, in accordance with many embodiments, the smart armor comprising an array of the piezoelectric composite material panel-sensors can be used in American football or other tactile sports to detect the location and magnitude of the impact force on the players during games. It should be understood that the smart armor of many embodiments may be used in various applications including but not limited to contact sports, non-contact sports, military equipment, first responder equipment, aerospace, and other related fields.

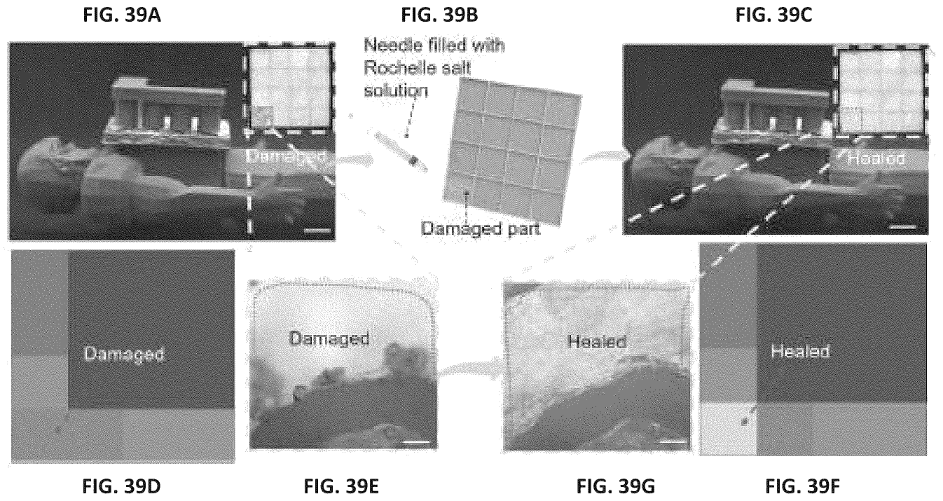

In many embodiments, the smart armor is healable and recyclable upon impact-caused damage or breakage, due to the healable and recyclable properties of the piezoelectric composite materials. FIG. 39A through FIG. 39F illustrate smart armor healability in accordance with an embodiment, wherein a smart armor was first constructed from a 4 by 4 array of panels comprising the piezoelectric composite material. FIG. 39A provides the RS crystals of one of the panels broken by an external impact. FIG. 39B provides the healing procedure applied to the broken panel, wherein the RS solution was injected into the damaged area of the panel using a needle, in accordance with many embodiments. The piezoelectric response of the smart armor before and after the healing process in accordance with an embodiment may then be analyzed using MATLAB pigment blocks, as shown by FIG. 39D and FIG. 39F respectively. The magnitude of the piezoelectric response of the smart armor at different stages is determined using MATLAB pigment blocks to visualize the output voltage. Furthermore, a 3D-printed L-shaped weight of 10 g is used for free-fall impact measurements, wherein the output voltage is collected for presentation as a MATLAB pigment block. FIG. 39D shows that, prior to the repair, the smart armor's sensitivity is impacted by the damage, due to the disconnection of the RS crystals from the scaffold shown in FIG. 39E. However, FIG. 39F illustrates an improved output voltage response after the healing process in accordance with an embodiment. Furthermore, FIG. 39E and FIG. 39G show the top partial view of a damaged and a healed panel, respectively, under an optical microscope in accordance with various embodiments. Accordingly, the smart armor of many embodiments is healable in a straightforward, economic, and facile manner.

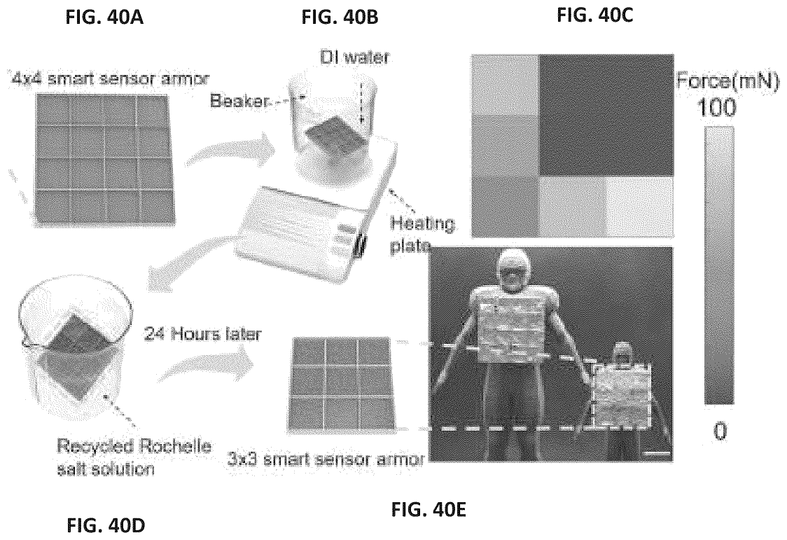

The recyclable properties of the smart armor of many embodiments, allow for facile adjustments to accommodate various body types, weights, and sizes, among many other advantages. FIG. 40A illustrates a first smart armor, in accordance with an embodiment, constructed from a 4 by 4 array of panels comprising the piezoelectric composite material. FIG. 40B illustrates the immersion of the 4 by 4 panel in distilled water heated to 80°, which caused the RS crystals within the panels to melt completely in accordance with an embodiment. FIG. 40D illustrates the first smart armor may be removed from the resulting solution, and the second smart armor constructed from a 3 by 3 array of panels comprising the bio-inspired scaffold is immersed into the same RS solution. As provided in FIG. 40E, as soon as the RS solution had completely soaked into the panels of the second smart armor, it is also removed from the solution and allowed to rest at room temperature for another 24 hours. Next the smaller second smart armor is subjected to the same free-fall impact measurements with a 3D-printed L-shaped weight of 10 g. FIG. 40C provides the collected output voltage, analyzed with MATLAB. As shown in FIG. 40C, the recycled smaller armor retains the piezoelectric properties of the original smart armor. Accordingly, MATLAB is used to calculate the pigment block, of FIG. 40C, utilizing the corresponding output voltage, confirming that, based on the output voltage of the recycled, 3 by 3 array-large, second smart armor, it is able to successfully sense the L-shaped weight, further highlighting the excellent sustainability potential of the smart armors assembled from the piezoelectric composite materials of many embodiments.

Piezoelectric Panel Incorporated into Smart Pads

In many embodiments, the biomimetic, piezoelectric composite materials provide superior protection and remarkable piezoelectric sensing capabilities when used in a smart protective pad that provides integrated mechanical protection and electrical sensitivity for high falling risk population. Protective knee pads are a critical need for many older people at high risk of falling in their daily lives. However, most knee pads only provide mechanical protection and hinder the further development of smart protective devices for senior people. Accordingly, there exists a great need in the geriatric community for a smart knee pad that can provide mechanical protection, while also serving as a fall detection alarm, and collecting data for further medical treatment. It should be understood that the smart knee pad of many embodiments may be utilized in various applications, including but not limited to geriatric care, high fall risk care, and physical therapy treatments. It should also be understood that a smart protective pad of several embodiments may be configured into varying shapes, including but not limited to knee pads, elbow pads, helmets, shin guards, and wrist guards.

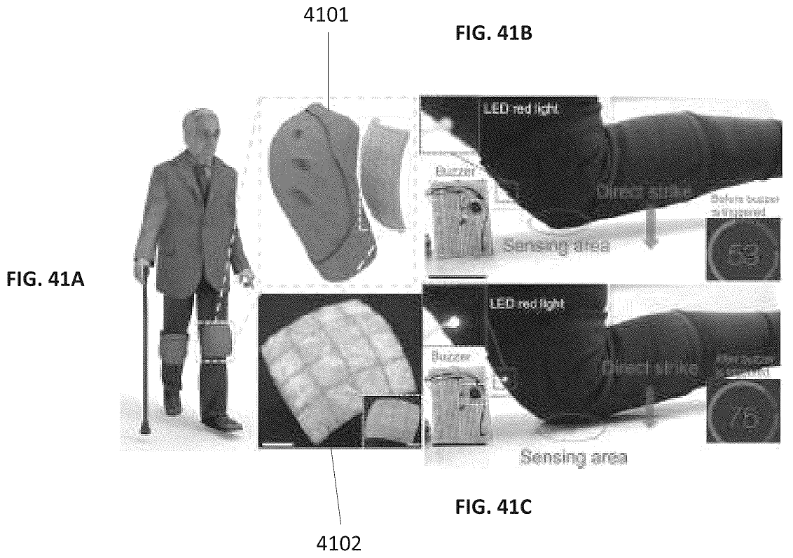

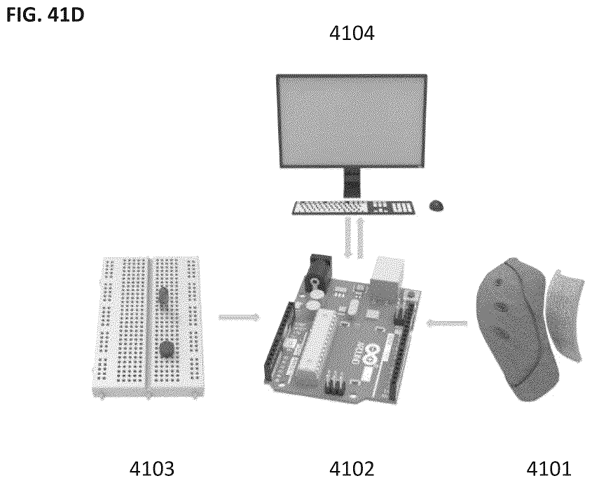

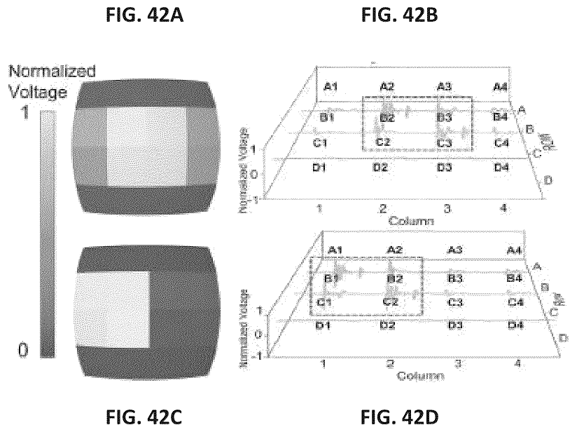

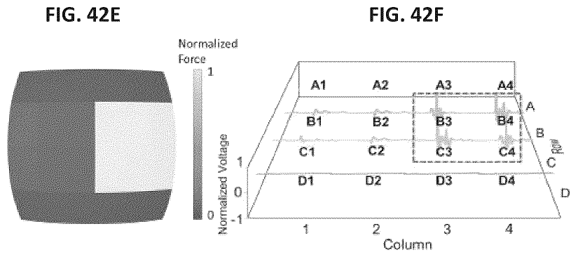

FIG. 41A provides, according to many embodiments, a curved pad that matches the shape of a human knee 4101 constructed from a 4 by 4 array of panels 4102, each comprising the 3D-printed bio-inspired scaffold filled with a crystallized RS sensing material. As provided in FIG. 41B through FIG. 41C, each panel element of the knee pad's 4 by 4 sensor panel array 4101 may be connected to an Arduino Uno 4102, a buzzer, and LED lights. As shown in FIG. 41D, all of the 16 panel elements of the knee pad's 4 by 4 array 4101 were plated with silver epoxy to serve as a positive and a negative electrodes, and connected to an Arduino Uno 4102 development board through a wire, with a breadboard 4103 functioning as a collection of circuit boards for connecting all 16 sensing panels to the Arduino Uno 4102 development board due to multiple lines. In addition, another breadboard connected to the Arduino Uno was used to install a buzzer alarm and LED lights, such that both the buzzer alarm and LED lights would get activated upon an impact on the fall detection knee pad. Moreover, a USB port was used to connect the Arduino Uno's 4102 power supply to the computer 4104, which, in turn, supplied 3.3 Volts to the circuit. In accordance with an embodiment, with the knee bent and the induction knee brace bound, the knee hit the ground at a vertical center knee impact, an inner knee impact, and an outer knee impact as shown in FIG. 41B and FIG. 41C. FIG. 42A provides the MATLAB pigment block diagram obtained from the detected voltage provided in FIG. 42B for a vertical center knee impact. FIG. 42C provides the MATLAB pigment block diagram obtained from the detected voltage provided in FIG. 42D for an inner knee impact.

In many embodiments, a knee covered by a smart knee pad is assessed during a fall test. FIG. 42E shows a 4 by 4 pigmented block calculated by MATLAB based on the voltage generated by the smart knee pad due to the impact of the fall. The four pigment blocks on the right side of the knee are clearly more stressed than their counterparts on the left side based on the voltage generated by the knee pad's piezoelectric effect. The output voltages after normalization for each pigment block, as shown in FIG. 42F, wherein the four individual panels on the right side of the knee pad generated a higher voltage, based on the fact that the right side of the knee had a higher force impact than the other side of the knee. Accordingly, it is possible to detect the location of a force impact and obtain its magnitude during the fall of the wearer of the smart knee pad comprising the piezoelectric composite material of many embodiments, by observing the resulting MATLAB pigment block diagram. As such, the smart knee pad also allows for the development of more effective knee protection, stemming from the data analysis it can provide for different falling positions.

In addition, the knee pad design of many embodiments presented herein may include an alarm buzz and or an LED light illumination upon detection of a fall event. In one particular, non-limiting example, the alarm's buzz and or LED light illumination threshold value for the smart knee pad of many embodiments is 1000 mV, wherein the buzzer sounds and the indicator LED light illuminates as soon as the voltage generated by the impact to the knee pad touching the ground exceeds 1000 mV, indicating detection of a fall event. In many embodiments, various alarm systems may be incorporated at different voltage output.

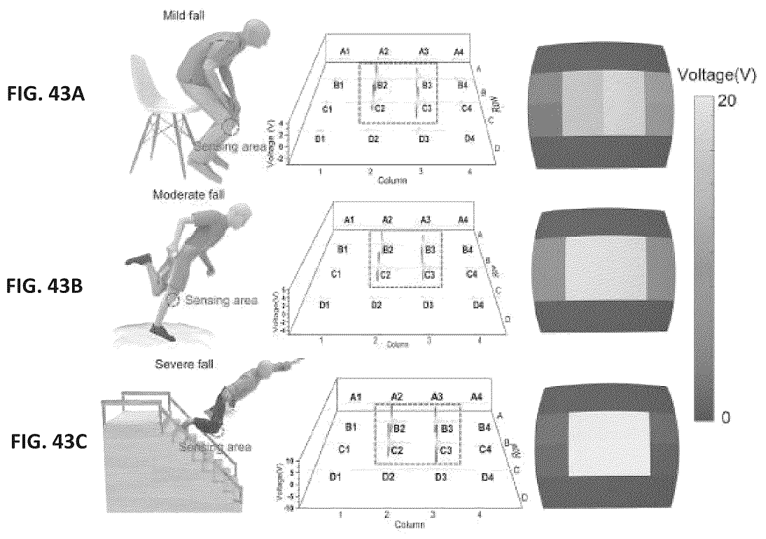

Moreover, in many embodiments, the knee pad described herein allows to evaluate the level of injury from a fall event. FIG. 43A, FIG. 43B, and FIG. 43C illustrate simulated falls to determine the levels of injury as mild, moderate, and severe, respectively. The level of the injury may be related to different types of falls by analyzing amplitude of the voltage generated by the knee pad of many embodiments upon an impact resulting from falls from different heights. FIG. 43A illustrates a fall from the chair results in a voltage of approximately 7V peak to peak generated in the middle part of the knee pad's sensing array comprising the piezoelectric composite material of many embodiments. Furthermore, FIG. 43B illustrates increasing the falling height to a standing starting position increases the voltage generated from the knee pad to 11V peak to peak. Moreover, FIG. 43C, further increasing the falling height to a few stair steps starting position increases the voltage output to 20V peak to peak. FIG. 43A through FIG. 43C present MATLAB pigment blocks analysis and piezoelectric curves that correspond to the different types of fall injuries. Accordingly, as demonstrated herein, and according to many embodiments, the instant knee pad allows for an easy and clear identification of the degree and location of a knee injury upon a fall event for further medical treatment. As such, the smart knee pad of many embodiments not only provides mechanical protection to the wearer, but also serves as a fall alarm and a fall data collecting sensor, thus enabling more specialized post-fall treatment.

### Exemplary Embodiment

In many embodiments, the size and shape of the bio-inspired scaffold may be precisely controlled in order to achieve the excellent mechanical properties of the instant piezoelectric composite materials. The bio-inspired scaffold may be formed through additive manufacturing techniques such as 3D-printing. In an embodiment, the 3D-printed bio-inspired scaffold may be modelled by “SolidWorks” and “Fusion 560” software. For several embodiments, the models may then be sliced as layers by “CHITUBOX” software to generate 2D patterns. In an embodiment, the bio-inspired scaffold may be fabricated with a commercial Digital Light Processing printer (Phrozon Sonic Mini 4 K, resolution: 35 μm) and industry-standard photocurable resin (Phrozon Auqa-Gray 4 K). The sliced image patterns may be projected on the resin surface through a glass tank and then cured via an LED optical system. In an embodiment, the first scaffold layer may be cured and attached to the substrate; afterward, the substrate may be moved up in one layer thicknesses for the cure of the second layer and so on. The printed scaffold layers may be attached to the bottom of the lifting substrate. For each layer to be able to be attached to the print platform, 2.5 seconds of exposure time may be set, followed by 35 seconds of exposure time at the bottom. In an embodiment, the curing time of 35 seconds is set at the bottom to ensure that the resin material can fully adhere to the printing platform and does not fall off, after that the curing time of each layer is set to 2.5 seconds to ensure the printing accuracy and prevent over-curing. After printing an embodiment, the samples may be washed using a 99% Isopropyl alcohol from a tank and post-cured in a UV chamber (Anycubic) for 15 min.

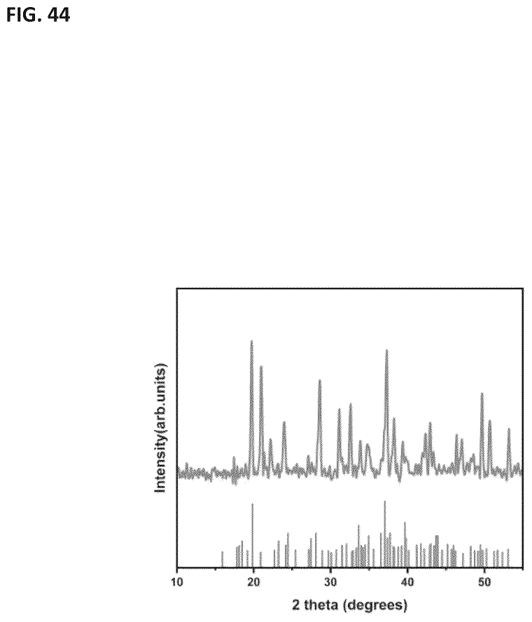

Many embodiments comprise bio-inspired scaffolds filled with a sensing material comprising crystallized RS. Sodium carbonate powder (produced by RUPERT, GIBBON & SPIDER, INC) and potassium bitartrate powder (produced by PURE SUPPLEMENTS) may be used as the starting materials of the RS solution in accordance with an embodiment. To prepare the RS solution, 80 g of potassium bitartrate powder are slowly poured into 100 ml of distilled water at 75° C. while stirring continuously. About one gram of sodium carbonate powder is periodically added to the continuously heated solution. The RS solution preparation is completed once all sodium carbonate powder has been added and bubbles are no longer present. In low light, at room temperature, a glass beaker containing the RS solution is left for 24 hours, resulting in large, nearly transparent crystals. In many embodiments, in order to adhere the RS crystals within the voids within the bio-inspired scaffold and to achieve a denser growth, the RS crystals are dissolved in a glass beaker heated to 100° C., followed by 15 minute evaporation of the distilled water vapor. In some embodiments, after allowing the solution to stand for 24 hours, three to five repetitions of the steps listed above may be performed. The dense distribution of the RS crystals is observed within the scaffold. Each crystal particle measured approximately 50 μm in size. To verify the crystallization of RS in the scaffold's polymer, an X-ray Diffraction is performed on a cross-section of a freshly broken RS crystal incorporating polymer is shown in FIG. 44.

Preparation of piezoelectric devices may be accomplished by fully immersing the 3D-printed polymeric scaffolds in the RS solution for one hour, followed by removal of the scaffolds from the solution, and resting the scaffolds for different times (60 minutes to 48 hours), in accordance with various embodiments. The bio-inspired polymeric scaffolds are first 3D-printed to have the dimensions of 10 mm×10 mm×3 mm. This scaffold may then be immersed into melted, prepared RS (sodium potassium tartrate tetrahydrate, NaKC₄H₄O₆·4H₂O) medium in a glass dish to allow the solution to penetrate the scaffold's inner structure. Afterward, the scaffold is removed from the solution and aired to allow for the attachment of the RS crystal to the internal microstructure of the scaffold. An embodiment is provided in FIG. 12A thru FIG. 12F, showing the RS crystals initially attach to the walls of the scaffold, however, as the air exposure time increases, the RS crystal gradually extends outward along the wall length and thickness, eventually filling the entire void space of the scaffold. As shown in FIG. 9A through FIG. 9E, more and more RS crystals fill the void space of the scaffold over hours. In this embodiment, the crystal growing process for each specific time duration is characterized by an optical microscope, SEM (FEI Quanta 550 FEG Scanning Electron Microscope, USA), and CT scanning (micro-CT instrument, Zeiss/Xradia 510 Versa, Germany). After the first 3 hours, a few solid crystals are observed to randomly attach to the scaffold walls. However, after 6 hours, the scaffold walls are fully wrapped with RS crystal, thus forming the 3D-printed-RSC in accordance with many embodiments.

In some embodiments, the smart armor described herein has dimensions of 5.5 cm, 5.5 cm, and 5 mm in length, width, and height, respectively; and consist of four-by-four sensing pixels/panels, each measuring 1 cm by 1 cm by 3 mm. To perform the healing process in accordance with an embodiment, the RS solution is first injected into the damaged area of the smart armor, and the smart armor is then allowed to rest for 24 hours in order to obtain the restored smart armor.

### Piezoelectric Response Testing of Exemplary Embodiments

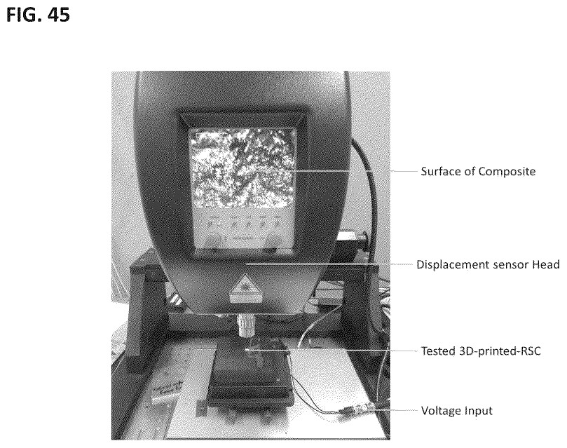

In many embodiments, the piezoelectric properties of the piezoelectric composite material are tested based on the piezoelectric response of the sensing material. Piezoelectricity without the need for poling is a natural property of RS. Furthermore, the piezoelectric responses of RS, in accordance with many embodiments, can be measured in almost all axes with three non-neglectable orthogonal piezoelectric coefficients in RS (d₁₄, d₂₅, d₃₆). The piezoelectric response of the piezoelectric composite materials of embodiments is tested using a piezoelectric composite material sample with 24 hours of the RS crystal growth within the bio-inspired polymeric scaffold. In an embodiment, the piezoelectric composite material's two sides are covered by silver electrodes, and the sample used for measurements. In an embodiment, the copper wires are used as the external electrodes to connect the composite sample to Analog Discovery 2 (Digilent 510-521, Digilent Co. WA, USA) to measure the generated output voltages induced by an applied external stress. The effective piezoelectric coefficient d₃₃ may be characterized by a d³³ meter (YE2730A, APC International, Ltd., Mackeyville, PA, USA). The vibrometer (Polytec MSA-600 Micro System Analyzer, Germany) may be used to obtain displacement and phase data of the composite samples. The electrical impedance of the composite samples may be measured by impedance analyzer (Agilent 4394 A, Santa Clara, CA, USA) in accordance with various embodiments. To measure out-of-plane displacement modules and phase changes in the tested samples of the piezoelectric composite material of some embodiments, the actuating conditions (−10 V to 10 V sinusoidal input voltage from 0 Hz to 20 KHz) can applied to the samples that are placed in a laser vibrometer (MSA-600 from Polytec), as shown in FIG. 45.

### Mechanical Testing of Exemplary Embodiments

In several embodiments, the mechanical properties of the piezoelectric composite material are tested based on the mechanical response of the piezoelectric composite material and the bare bio-inspired scaffold. A universal testing machine (Instron 34SC-1, MA, USA) may be used to measure the mechanical properties of various embodiments comprising both the bare scaffolds and the scaffolds filled with the RS crystal. All samples may be placed on the testing platform, and a compressive force applied vertically to the tested samples. In the static compression test of an embodiment, a compressive velocity of 0.5 mm/s is set with a maximum compression distance of 7 mm. In the three-point bending test of an embodiment, a compressive velocity of 0.5 mm/s and a maximum compression distance of 3 mm are selected and applied to the samples with or without notches. For the single-edge notched bend tests of several embodiments, the scaffold samples are 3D-printed to have a thickness of 5 mm and a notch depth of 0.6 mm, before being filled with the RS crystal growth of 0 to 24 hours.

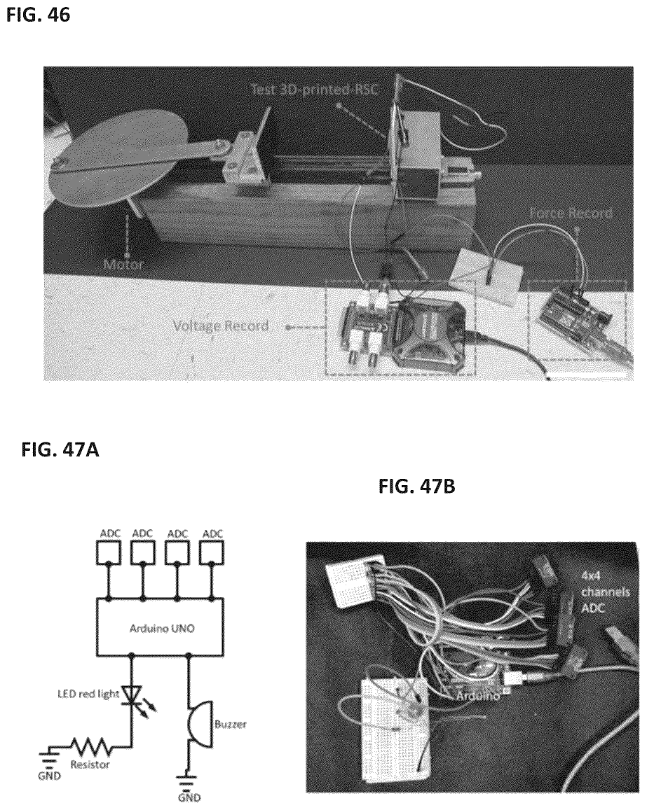

FIG. 46 provides a motor-driven cyclic impact test experimental set-up to assess the piezoelectric performance of many embodiments. The force level of the rocker arm and the frequency of the rocker arm motion are adjusted by changing the motor input voltage. A pulley system on the bottom of the set-up allows the distance between the tested embodiment to also be easily adjusted. The accuracy of the magnitude of the recorded force may be ensured by a thin film force sensor.

The pictures of the crack's side view may be obtained instantly by SEM and provided in FIG. 21. Equation 5 and Equation 6 provide the fracture toughness for crack initiation (K_{IC}):

$${K}_{IC} = \frac{P \times S}{{BW}^{\frac{3}{2}}} \times f ( \frac{a}{W} ) \qquad ( EQ . 5 )$$

$$f ( \frac{a}{W} ) = \frac{3 {( \frac{a}{W} )}^{\frac{1}{2}} \times [ 1.99 - ( \frac{a}{W} ) ( 1 - \frac{a}{W} ) ( 2.15 - 3.96 ( \frac{a}{W} ) + {( \frac{a}{W} )}^{2} ) ]}{2 ( 1 + 2 \frac{a}{W} ) \times {( 1 - \frac{a}{W} )}^{\frac{3}{2}}} \qquad ( EQ . 6 )$$

Wherein, in an embodiment, P is the maximum load during the test, S is the support span (2 cm), a is the notch depth (0.6 mm), W is the sample width (5 mm), and B is the thickness of the sample (3 mm). To further calculate and analyze the fracture toughness for crack propagation (K_{JC}), the J-integral equation may be utilized. The J-integral equation based on the elastic and plastic contribution can be presented as J=Jₑₗ+Jₚₗ·Jₑₗ is the elastic component, which can be calculated via Equation 7 and Equation 8:

$${J}_{el} = \frac{{K}_{IC}^{2}}{E ′} \qquad ( EQ . 7 )$$

$${E}^{′} = {E ( 1 - v )}^{2} \qquad ( EQ . 8 )$$

In an embodiment, wherein E is Young's modulus, and vis the Poisson's ration. Furthermore, Jₚₗ, the plastic component can be calculated as Equation 9:

$${J}_{pl} = \frac{2 {A}_{pl}}{B ( W - a )} \qquad ( EQ . 9 )$$

In an embodiment, wherein Aₚₗ is the plastic area under the load-displacement curve. Thus, the K_{JC} is determined in Equation 10 by transforming J-integral equation:

$${K}_{JC} = {( {JE}^{′} )}^{\frac{1}{2}} \qquad ( EQ . 10 )$$

The crack extension (Δα) of an embodiment is then related via Equation 11 through Equation 13:

$${a}_{n} = {a}_{n - 1} + \frac{( w - {a}_{n - 1} )}{2} \times \frac{( {C}_{n} - {C}_{n - 1} )}{{C}_{n}} \qquad ( EQ . 11 )$$

$${C}_{n} = \frac{{u}_{n}}{{f}_{n}} \qquad ( EQ . 12 )$$

$$Δ a = {a}_{n} - a \qquad ( EQ . 13 )$$

Wherein aₙ, Cₙ, uₙ, and fₙ represent crack length, complaisance, displacement, and force at each point after the departure of the crack, respectively, in accordance with an embodiment. A mechanical test may be conducted using ten samples under the same conditions to reduce experimental error in accordance with various embodiments.

### Modeling of Simulation of the Piezoelectric Response and Mechanical Testing of Exemplary Embodiments

The piezoelectric composite material models of various embodiments may be designed and optimized in Solidworks software. Many embodiments of the modeled piezoelectric composite materials may then be imported into COMSOL Multiphysics version 5.6 for simulation of the piezoelectric response and mechanical tests. In the piezoelectric simulation, mechanical deformation occurs through the whole composite structure, inducing the piezoelectric potential emerging on the top and bottom sides of the composite with electrodes. The potential piezoelectric property of the piezoelectric composite materials of some embodiments may be tested by the application of a force (10N) to achieve the deformation and the piezoelectric output. Moreover, in mechanical test simulations, a compressive force may be applied as 1 N to study the crack deflection and deformation of bare and the RS crystal-filled scaffolds of various embodiments. The piezoelectric coefficient of RS may be obtained by COMSOL Multiphysics® software to collect the material references.

Piezoelectric Response and Mechanical Testing of an Exemplary Embodiment Incorporated into Smart Armor

Many embodiments of the piezoelectric composite material may be incorporated into a panel comprising many piezoelectric composite materials. Further embodiments of the piezoelectric panel may be incorporated into smart armor. An exemplary embodiment of the smart armor may have dimensions of 5.5 cm, 5.5 cm, and 5 mmin length, width, and height, respectively. An embodiment of the smart armor may consist of four-by-four sensing panel elements, in accordance with various embodiments, each measuring 1 cm by 1 cm by 3 mm. To form positive and negative electrodes of many embodiments, E-solder (VonRoll, USA, Inc) may be evenly deposited over the upper and lower surfaces of each sensing element panel as provided in FIG. 35A. In many embodiments of the data collection process, each signal acquisition panel element may be connected on a 4×4 panel to a Single-board microcontroller (Arduino). An embodiment of the smart armor may be laid over a 3D-printed athlete model, in turn laid on a flat table. In various embodiments of the data collection process different weights may be allowed to fall vertically downward onto the smart armor embodiment from an identical height in order to simulate the impact of a soccer (or another) ball, or, as another example, athletes' elbows, striking the smart armor during a game.

Piezoelectric Response and Mechanical Testing of an Exemplary Embodiment Incorporated into a Fall Detection Knee Pad

Many embodiments of the piezoelectric composite material may be incorporated into a panel comprising many piezoelectric composite materials. Further embodiments of the piezoelectric panel may be incorporated into a smart knee pad. Many embodiments of the smart knee pad may be further incorporated into a fall detection system. In several embodiments, to better fit the curvature of the knee, the smart knee pad may be designed to bend on the x-axis and y-axis simultaneously instead of a flat surface. An embodiment of the smart knee pad may measure 5.5 cm, 5.5 cm, and 5 mm in length, width, and height, respectively. An embodiment of the smart knee pad may have a four-by-four sensing element panel measuring 1 cm by 1 cm by 3 mm. Using an Arduino microcontroller, the output voltage for compressing the smart knee pad of various embodiments may be measured. Many embodiments of the smart knee pad may also be connected to a red LED light and an alarm buzzer to alert to fall events. Some embodiments of the smart knee pad may consist of four 4×4 elements connected to a four-channel ADC; and the alarm trigger threshold may be set at 900 mV as shown in FIG. 47A and FIG. 47B.

### Doctrine of Equivalents

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the,” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. Where ranges are described, the range should be understood to include the endpoints of the ranges, and the endpoints of such ranges are also contemplated to stand on their own as inventive, individual data points and to form the endpoints of other ranges. For example, a ratio in the range of about 1 to about 200 should be understood to include the explicitly recited limits of about 1 and about 200, but also to include individual ratios such as about 2, about 3, and about 4, sub-ranges such as about 1 to about 10, about 10 to about 50, about 20 to about 100, about 100 to about 200, and so forth, and related ranges such as greater than about 1 or less than about 200.

What is claimed is:

1. A piezoelectric composite material comprising:
a scaffold comprising an irregular internal structure further comprising a plurality of voids, channels, and wall-septa; and
a sensing material comprising piezoelectric properties disposed within the irregular internal structure of the scaffold, and wherein the sensing material crystallizes within the irregular internal structure.

2. The piezoelectric composite material of claim 1, wherein the irregular internal structure further comprises interconnected channels.

3. The piezoelectric composite material of claim 1, wherein the irregular internal structure comprises a bio-inspired structure.

4. The piezoelectric composite material of claim 1, wherein the scaffold is 3D-printed.

5. The piezoelectric composite material of claim 1, wherein the scaffold accounts for 20% of a piezoelectric composite material total volume.

6. The piezoelectric composite material of claim 1, wherein the sensing material comprises a Rochelle salt.

7. The piezoelectric composite material of claim 1, wherein the sensing material crystallizes within the scaffold such that the sensing material substantially fills the entirety of the plurality of voids and channels of the irregular internal structure of the scaffold.

8. The piezoelectric composite material of claim 1, wherein a plurality of piezoelectric composite materials are configured to be incorporated in a piezoelectric panel

9. The piezoelectric composite material of claim 8, wherein the piezoelectric panel is incorporated into smart armor.

10. The piezoelectric composite material of claim 8, wherein the piezoelectric panel is incorporated into a smart knee pad further comprising a buzzer and a light.

11. A process for healing a piezoelectric composite material comprising:
identifying a damaged area within the piezoelectric composite material;
providing a sensing material solution;
injecting the sensing material solution into the identified damaged area of the piezoelectric composite material; and
allowing the sensing material to crystallize within the piezoelectric composite material.

12. The process of claim 11, further comprising allowing the sensing material to crystallize for 24 hours.

13. The process of claim 11, further comprising allowing the sensing material to crystallize at room temperature.

14. The process of claim 11, wherein the sensing material comprises Rochelle salt.

15. A process for recycling a piezoelectric composite material comprising:
providing heated distilled water;
immersing a first piezoelectric composite material comprising a first scaffold and a first sensing material in the heated distilled water;
allowing the first sensing material to dissolve into the heated distilled water;
removing the first scaffold from the first sensing material and the heated distilled water solution;
immersing a second scaffold in the first sensing material and the heated distilled water solution; and
allowing the first sensing material to crystallize within the second scaffold.

16. The process of claim 15, further comprising immersing the first piezoelectric composite material in the heated distilled water such that the first sensing material completely dissolves.

17. The process of claim 15, wherein the first scaffold is bare when removed.

18. The process of claim 15, further comprising allowing the first sensing material to crystallize within the second scaffold for 24 hours.

19. The process of claim 15, further comprising allowing the first sensing material to crystallize within the second scaffold at room temperature.

20. The process of claim 15, wherein the first sensing material comprises a Rochelle salt.
